(19) United States
(12) Patent Application Publication
(10) Pub. No.: US 2026/0251447 A1
(43) Pub. Date: Aug. 27, 2026

(54) FLATNESS INSPECTION APPARATUS AND FLATNESS INSPECTION METHOD USING THE SAME

(71) Applicant: SAMSUNG DISPLAY CO., LTD., YONGIN-SI (KR)

(72) Inventor: JEONGWON HAN, Yongin-si (KR)

(21) Appl. No.: 19/360,036

(22) Filed: Oct. 16, 2025

(30) Foreign Application Priority Data
Feb. 18, 2025 (KR) 10-2025-0020488

(51) Int. Cl. G01B 11/30; G01N 21/95; H10P 72/72; H10P 74/00; H10P 74/20

(52) U.S. Cl. CPC G01B 11/306; G01B 11/303; G01N 21/9501; H10P 72/72; H10P 74/203; H10P 74/27; G01B 2210/56

(57) ABSTRACT

A flatness inspection apparatus includes an inspection stage having a first inspection position and a second inspection position. The second inspection position faces the first inspection position in a first direction. A non-contact optical system having a rotation axis is located between the first inspection position and the second inspection position, in a plan view defined by the first direction and a second direction intersecting the first direction. The non-contact optical system inspecting a shape of a first inspection surface of a first inspection object at the first inspection position and inspecting a shape of a second inspection surface of a second inspection object, at the second inspection position. A first rotator rotating the non-contact optical system about the rotation axis.

### CROSS-REFERENCE TO RELATED APPLICATION

This application claims priority under 35 U.S.C. §119 to Korean Patent Application No. 10-2025-0020488, filed on February 18, 2025 in the Korean Intellectual Property Office, the disclosure of which is incorporated by reference in its entirety herein.

### TECHNICAL FIELD

The present disclosure generally relates to a flatness inspection apparatus and a flatness inspection method. More specifically, the present disclosure relates to a flatness inspection apparatus and flatness inspection method using the flatness inspection apparatus under atmospheric pressure.

### DISCUSSION OF RELATED ART

Display devices provide an interface between users and visual information. Display devices are increasingly being applied to a variety of different electronic devices along with the advancement of information technology. Various types of display devices are widely used across different fields, including, for example, a liquid crystal display (“LCD”), an organic light-emitting display (“OLED”), and a plasma display (“PDP”).

A display device and an electronic apparatus including the display device may be fabricated by depositing a light-emitting material onto a substrate. For example, a micro-display, such as a virtual reality (“VR”), extended reality (“XR”), or augmented reality (“AR”) display, may be fabricated by depositing the light-emitting material onto a silicon wafer.

The silicon wafer has a curved surface. Accordingly, the deposition process may be performed after the flatness of the silicon wafer is increased using a chuck, such as an electrostatic chuck.

### SUMMARY

An embodiment of the present disclosure provides a flatness inspection apparatus configured to prevent deposition defects.

An embodiment of the present disclosure provides a flatness inspection method using the flatness inspection apparatus.

According to an embodiment of the present disclosure, a flatness inspection apparatus includes an inspection stage having a first inspection position and a second inspection position. The second inspection position faces the first inspection position in a first direction. A non-contact optical system having a rotation axis is located between the first inspection position and the second inspection position, in a plan view defined by the first direction and a second direction intersecting the first direction. The non-contact optical system inspecting a shape of a first inspection surface of a first inspection object at the first inspection position and inspecting a shape of a second inspection surface of a second inspection object, at the second inspection position. A first rotator rotating the non-contact optical system about the rotation axis.

In an embodiment, the inspection stage includes a plurality of inspection stages. The plurality of inspection stages may include a first inspection stage including the first inspection position and a second inspection stage including the second inspection position.

In an embodiment, the flatness inspection apparatus may further include a first guide guiding movement of the first inspection stage in the second direction and a direction opposite to the second direction; a second guide guiding movement of the second inspection stage in the second direction and the direction opposite to the second direction; a lifter located between the first guide and the second guide, spaced apart from both the first inspection position and the second inspection position in the second direction, and including a transfer stage moving up and down in the first direction in the plan view; and a second rotator flipping over the transfer stage between the first guide and the second guide.

In an embodiment, in the plan view, a first virtual line may be defined to overlap the first inspection position, the non-contact optical system, and the second inspection position, the first virtual line intersecting the inspection stage, a second virtual line is parallel to an extension direction of the lifter and intersects the inspection stage, and a loading position in which the first inspection object is placed may be located between the first virtual line and the second virtual line, and the flatness inspection apparatus moves the first inspection object from the loading position to the first inspection position along the first guide, moves the second inspection object from the loading position to the second inspection position along the second guide via the lifter and the second rotator.

In an embodiment, the flatness inspection apparatus may further include a first guide guiding movement of the first inspection stage in the second direction and the direction opposite to the second direction; a second guide guiding movement of the second inspection stage in the second direction and the direction opposite to the second direction; and a lifter located between the first guide and the second guide, spaced apart from both the first inspection position and the second inspection position in the second direction, and including a transfer stage moving up and down in the first direction in the plan view.

In an embodiment, in the plan view, a first loading position may overlap the first inspection position, a second loading position may overlap the transfer stage when the transfer stage included in the lifter is located at the lowest level, and the flatness inspection apparatus moves the second inspection object from the second loading position to the second inspection position along the second guide via the lifter.

In an embodiment, the inspection stage rotates in conjunction with the non-contact optical system, when the non-contact optical system does not rotate and is in a first orientation, the flatness inspection apparatus inspects the first inspection object at the first inspection position, and when the inspection stage and the non-contact optical system rotate from the first orientation to a second orientation, the flatness inspection apparatus inspects the second inspection object at the second inspection position.

In an embodiment, the first and second inspection objects may be selected from a group consisting of an electrostatic chuck, a silicon wafer, a mask, and a mask support.

In an embodiment, the silicon wafer may be included in a display device including a light-emitting material, or in an electronic device that includes the display device.

According to an embodiment of the present disclosure, a flatness inspection apparatus includes a first inspection stage having a first inspection position; a second inspection stage having a second inspection position facing the first inspection position in a first direction; a first non-contact optical system inspecting a shape of a first inspection surface of a first inspection object at the first inspection position; and a second non-contact optical system inspecting a shape of a second inspection surface of a second inspection object at the second inspection position.

In an embodiment, the flatness inspection apparatus may further include a rotator flipping the second inspection stage over.

In an embodiment, in a plan view defined by the first direction and a second direction intersecting the first direction, the first loading position may overlap the first inspection position, the second loading position may overlap the second inspection stage when the second inspection stage is located at a level prior to being flipped over by the rotator, and the second inspection object may be located at the second inspection position by flipping the second inspection stage over by the rotator.

In an embodiment, an inspection object may be selected from a group consisting of an electrostatic chuck, a silicon wafer, a mask, and a mask support.

In an embodiment, the silicon wafer may be included in a display device including a light-emitting material, or in an electronic device that includes the display device.

According to an embodiment of the present disclosure, a flatness inspection method includes: placing a first inspection object at a first inspection position; inspecting, in a non-contact manner, a surface shape of a first inspection surface of the first inspection object by a non-contact optical system; placing a second inspection object at a second inspection position facing the first inspection position in a first direction; inspecting, in a non-contact manner, a surface shape of a second inspection surface of the second inspection object by the non-contact optical system; and determining whether a flatness inspection result meets a predetermined criterion.

In an embodiment, the step of placing the first inspection object at the first inspection position may include: placing the first inspection object on a first inspection stage that includes a loading position and locating the first inspection object at the first inspection position by moving the first inspection stage in a second direction intersecting the first direction, and the step of placing the second inspection object at the second inspection position may include: placing the second inspection object on the first inspection stage that includes the loading position; locating the first inspection stage under a transfer stage by moving the first inspection stage in the second direction; transferring the second inspection object from the first inspection stage to the transfer stage; flipping over the transfer stage and moving the transfer stage in the first direction; transferring the second inspection object from the flipped over transfer stage to the second inspection stage; and locating the second inspection object at the second inspection position by moving the second inspection stage in a second direction intersecting the first direction, and the step of inspecting the surface shape of the second inspection surface may include: rotating the non-contact optical system, which has inspected the first inspection position while in a first orientation, towards the second inspection position from the first orientation to a second orientation, and inspecting the second inspection surface.

In an embodiment, if the flatness inspection result meet the predetermined criterion, the first inspection object and the second inspection object may be used in a deposition process.

In an embodiment, if the flatness inspection result does not meet the predetermined criterion, the first inspection object and the second inspection object may be discarded or subjected to a reprocessing step.

In an embodiment, the step of placing the first inspection object at the first inspection position may include: placing the first inspection object on a first inspection stage that includes a first loading position, the step of placing the second inspection object at the second inspection position may include: placing the second inspection object on a transfer stage that includes a second loading position; moving the transfer stage in the first direction; transferring the second inspection object from the transfer stage to a second inspection stage; and locating the second inspection stage at the second inspection position by moving the second inspection stage in an opposite direction to the second direction, and the step of inspecting the surface shape of the second inspection surface may include: rotating the non-contact optical system, which has inspected the first inspection position while in a first orientation, towards the second inspection position from the first orientation to a second orientation, and inspecting the second inspection surface.

In an embodiment, the step of placing the first inspection object at the first inspection position may include: placing the first inspection object on an inspection stage that includes a loading position, and the step of placing the second inspection object at the second inspection position may include: placing the second inspection object on the inspection stage that includes the loading position; and locating the second inspection object at the second inspection position by rotating in conjunction with the non-contact optical system.

A flatness inspection apparatus and a flatness inspection method using the flatness inspection apparatus may inspect an inspection object deformed by gravity at a second inspection position. If the inspection object does not deform by gravity (or is at a negligible level), the inspection object may be inspected at only a first inspection position. Accordingly, flatness inspection may be performed in an environment identical to an actual deposition environment.

In addition, the flatness inspection apparatus and the flatness inspection method may inspect the surface shape deformed by gravity (e.g., flatness of a chuck, flatness of a substrate (e.g., surface shape), flatness of a mask support, amount of sagging of mask, or the like), in an atmospheric environment. Based on the inspection result, the inspection object may or might not be used in the deposition process. By inspecting before the deposition process, the reliability of the deposition quality may be increased.

### BRIEF DESCRIPTION OF THE DRAWINGS

The accompanying drawings, which are included to provide a further understanding of the present disclosure, illustrate non-limiting embodiments of the present disclosure together with the description thereof, in which:

FIGS. 1 and 2 are views illustrating a flatness inspection apparatus according to embodiments of the present disclosure.

FIG. 3 is a flow chart illustrating a flatness inspection method using the flatness inspection apparatus of FIG. 1.

FIGS. 4, 5, 6, 7, 8, 9, 10, 11, 12, 13, 14, 15, 16, 17, 18, 19, 20, 21, 22 and 23, are views illustrating the flatness inspection method according to embodiments of the present disclosure.

FIG. 24 is a view illustrating illustrate a flatness inspection apparatus according to an embodiment of the present disclosure.

FIGS. 25, 26, 27, 28 and 29, are views illustrating the flatness inspection method using the flatness inspection apparatus of FIG. 24 according to embodiments of the present disclosure.

FIG. 30 is a view illustrating a flatness inspection apparatus according to an embodiment of the present disclosure.

FIGS. 31, 32 and 33, are views illustrating a flatness inspection method using the flatness inspection apparatus of FIG. 30 according to embodiments of the present disclosure.

FIGS. 34 and 35 are views illustrating a flatness inspection apparatus according to embodiments of the present disclosure and a flatness inspection method using the same.

FIG. 36 is a view illustrating the deposition process using the inspected inspection object by the flatness inspection apparatus and the flatness inspection method using the same according an embodiment of the present disclosure.

FIG. 37 is a block diagram illustrating an electronic device according to an embodiment.

FIG. 38 is a schematic diagram of an electronic device according to an embodiment.

FIG. 39 is a view illustrating a display device according to an embodiment of the present disclosure.

FIG. 40 is a block diagram illustrating the display device of FIG. 39.

### DETAILED DESCRIPTION OF EMBODIMENTS

Non-limiting embodiments of the present disclosure will be more clearly understood from the following detailed description in conjunction with the accompanying drawings. Like reference numerals or symbols refer to like elements throughout, and overlapping descriptions of the same components may be omitted.

A display device according to an embodiment may be applied to various electronic devices. An electronic device according to an embodiment may include the display device and may include additional modules or devices having other additional functions in addition to the display device.

The present disclosure concerns a flatness inspection apparatus that includes at least one non-contact optical system which inspects an object without making physical contact with the object. The non-contact optical system prevents deformation or error of the inspected object by avoiding physical contact with the object.

The flatness inspection apparatus allows for the inspection of the flatness of an object, such as a flatness of a chuck, a substrate, a mask support, etc., in atmospheric conditions, and prior to the performing of a deposition step. Therefore, the flatness inspection apparatus provides a more efficient inspection process which reduces the time for performing the process and eliminates the cost of deposition on a defective element.

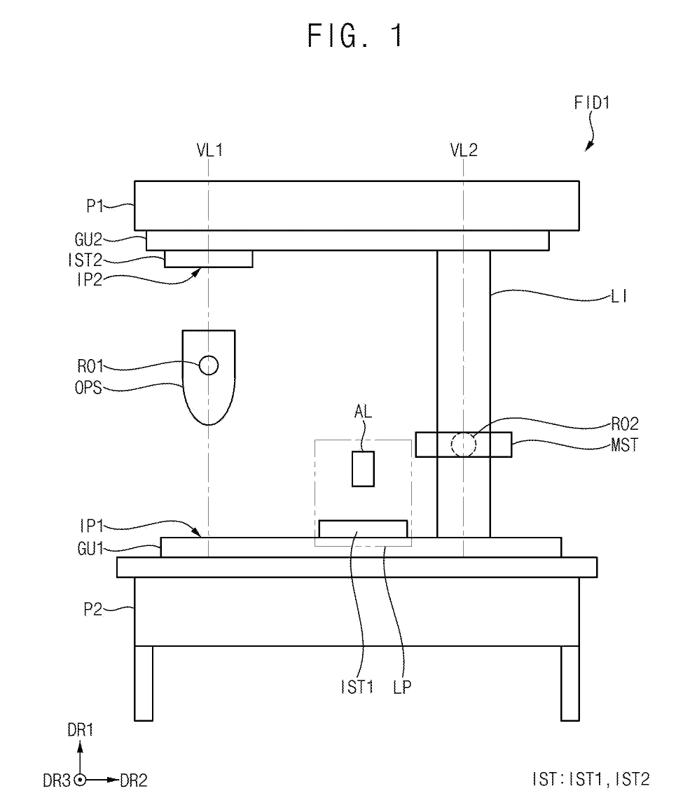

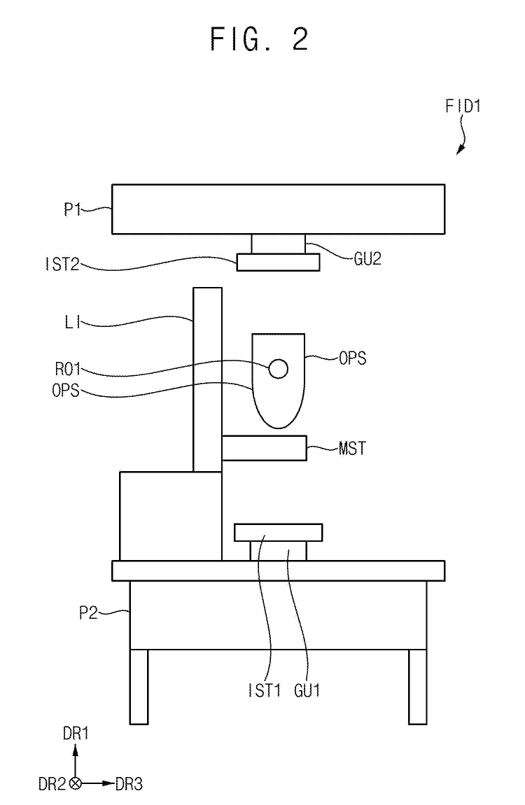

FIGS. 1 and 2 are views illustrating a flatness inspection apparatus according to embodiments of the present disclosure.

Referring to FIGS. 1 and 2, a flatness inspection apparatus FID1 according to an embodiment of the present disclosure may include an inspection stage IST, a non-contact optical system OPS, a first rotator RO1, a first guide GU1, a second guide GU2, a lifter LI, and a second rotator RO2.

In an embodiment, the inspection stage IST may include a first inspection position IP1 and a second inspection position IP2 facing the first inspection position IP1 in a first direction DR1.

In an embodiment, the inspection stage IST may include a plurality of inspection stages. In an embodiment, the plurality of inspection stages IST may include a first inspection stage IST1 including the first inspection position IP1 and a second inspection stage IST2 including the second inspection position IP2.

In an embodiment, the non-contact optical system OPS may include a rotating axis located between the first inspection position IP1 and the second inspection position IP2 in a plan (hereinafter, referred to as "a side") view defined by the first direction DR1 and a second direction DR2 intersecting the first direction DR1.

In an embodiment, the non-contact optical system OPS may inspect a shape of a first inspection surface of a first inspection object at the first inspection position IP1 and may also inspect a shape of a second inspection surface of a second inspection object that is deformed by gravity, at the second inspection position IP2.

For example, the optical system OPS may be used without restriction as long as it is a device that may inspect a shape of a surface in a non-contact manner.

For example, in an embodiment the optical system OPS may use a coordinate measuring machine (“CMM”) and an auto focus sensor, a confocal displacement sensor, a laser displacement sensor, a capacitance sensor, an eddy-current sensor, a multi-beam optical sensor (“MOS”), or the like. The optical system OPS may inspect the shape of the inspection surface (e.g., the first inspection surface and the second inspection surface) point by point.

By integrating the CMM into the auto focus sensor, the CMM and the auto focus sensor may be a device that measure the shape of the inspection surface in a non-contact manner. For example, the auto focus sensor using an optical or laser sensor may automatically adjust a focus, resulting in greater speed and precision.

In an embodiment, the confocal displacement sensor may be a device that measures a height, micro-structure, thickness, or the like of the inspection surface in a non-contact manner. For example, a confocal chromatic sensor may measure a distance of a surface using light in different wavelength bands and may determine an exact distance using a chromatic aberration principle. The confocal displacement sensor may also measure a transparent material such as silicon.

The laser displacement sensor may be a device that may measure a distance between the inspection surface and the sensor (e.g., a thickness of the object, a height of the object surface, or the like) in a non-contact manner using a triangulation principle and confocal method. Laser light may be projected onto the inspection surface, and a distance may be calculated by measuring an angle of a reflected light. When using the confocal method, the laser light may be projected to a specific focal point, and a distance may be calculated by measuring the angle of the reflected light.

The capacitive sensor may be a device that may measure a position, distance, thickness, material conversion of an object by using a material between two electrodes, permittivity of the object, change in a gap, or the like. The capacitive sensor may have a fast reaction speed.

The eddy current sensor may measure a distance in a non-contact manner using a principle of electromagnetic induction. The eddy current sensor may provide high linearity, high-speed measurement, and high resolution.

In an embodiment, the multi-beam light sensor may measure a stress and a curvature of the inspection surface in real time using multiple beams. For example, the multi-beam light sensor may be used primarily to monitor stress and curvature changes during thin film deposition or heat treatment processes.

However, embodiments of the present disclosure are not necessarily limited thereto. For example, the optical system OPS may use a laser Fizeau interferometer, a phase measuring deflectometry (“PMD”), an area scan interferometer, or the like. The optical system OPS may inspect the shape of the inspection surface (e.g., the first inspection surface and the second inspection surface) face by face.

In an embodiment, the laser Fizeau interferometer may be a device that may measure the shape of the surface or a quality of an optical component with high precision by using an interference phenomenon of light. For example, in an embodiment the optical system OPS may divide one laser beam into a reference beam and an inspection beam, project each onto a high-quality surface and an inspection surface, and then analyze interference fringes of the reflected light. For example, in an embodiment, through an interference pattern, the height, thickness, shape, or the like of the inspection surface may be measured.

The PMD is a device that may measure a three-dimensional shape in a non-contact manner. The PMD may project a periodic pattern on a screen, and a distortion of the pattern projected on the inspection surface may measure a height, slope, or the like of the inspection surface. For example, the PMD may provide high accuracy in nano-meters.

The surface scanning interferometer may be a device that may measure surface features or defects in high resolution using an interferometer. The surface scanning interferometer can scan images of a large area at once to analyze surface shapes, providing high resolution and high accuracy.

By using the non-contact optical system OPS, it is possible to prevent deformation or error of the inspected object due to contact. In addition, it is possible to detect the shape of the surface of various inspected objects.

In an embodiment, the first rotator RO1 may rotate about the rotation axis of the non-contact optical system OPS. For example, the rotation axis may be arranged to extend in a third direction DR3.

In an embodiment, the first guide GU1 may guide a path of the first inspection stage IST1 along the second direction DR2.

In an embodiment, the second guide GU2 may guide a path of the second inspection stage IST2 in the second direction DR2.

In an embodiment, the lifter LI may be located between the first guide GU1 and the second guide GU2 (e.g., in the first direction DR1). The lifter LI may be spaced apart from the first inspection position IP1 and the second inspection position IP2 in the second direction DR2, and may include a transfer stage MST that lifts and lowers (e.g., moves up and down) the inspection object in the first direction DR1.

In an embodiment, the second rotator RO2 may flip over (e.g., invert in an angle of 180°) the transfer stage MST between the first guide GU1 and the second guide GU2.

In an embodiment, in a side view, a loading position LP in which the inspection object is seated may be located between a first virtual line VL1 and a second virtual line VL2.

The first virtual line VL1 may be defined as a line extending in the first direction DR1 and overlapping the first inspection position IP1, the non-contact optical system OPS, and the second inspection position IP2, and intersecting the inspection stage IST. The second virtual line VL2 may be defined as a line parallel to the extension direction of the lifter LI (e.g., first direction DR1) and intersecting the inspection stage IST.

The inspection object may move from the loading position LP to the first inspection position IP1 by the first guide GU1, and from the loading position LP via the lifter LI and the second rotator RO2 to the second inspection position IP2 by the second guide GU2.

However, embodiments of the present disclosure are not necessarily limited thereto. For example, the flatness inspection apparatus FID1 may include more components, or some of the components may be omitted/replaced.

For example, in an embodiment the flatness inspection apparatus FID1 may include an additional alignment camera AL, for example, the alignment camera AL may verify that the inspection object is seated in a correct position at the loading position LP.

For example, the inspection stage IST is described as being located on a surface plate (P1, P2). However, embodiments of the present disclosure are not necessarily limited thereto.

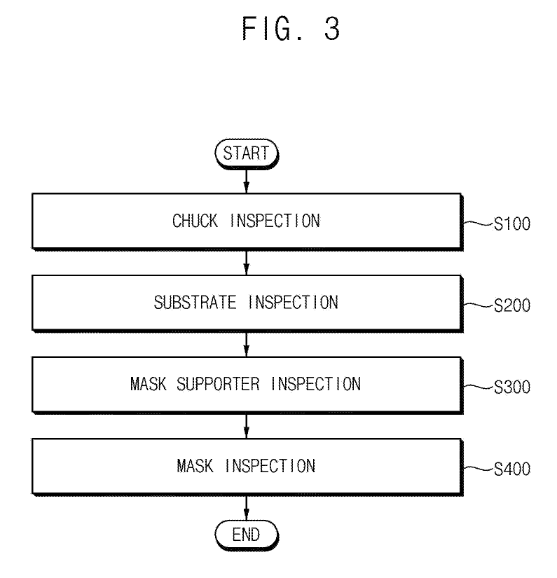

FIG. 3 is a flow chart illustrating a flatness inspection method using the flatness inspection apparatus of FIG. 1.

Referring to FIG. 3, in an embodiment, the inspection object may be selected from a group consisting of a chuck (e.g., electrostatic chuck), a substrate (e.g., a silicon wafer), a mask, and a supporter for supporting the mask.

In an embodiment, the flatness inspection method according to embodiments of the present disclosure may include chuck inspection in step S100, substrate inspection in step S200, mask support inspection in step S300, and mask inspection in step S400.

To increase the flatness of the substrate and reduce a sagging of the mask, a deposition facility may include a first chuck for the substrate and a second chuck for the mask. The flatness of the chuck (e.g., the first chuck and the second chuck), the flatness of the substrate, the flatness of the mask support, and the amount of sagging of the mask may affect a reliability of a deposition quality.

Conventionally, to find a cause of a deposition failure, the deposition facility was stopped and the cause analysis was performed. In this case, additional time was required for the analysis of the cause, and a cost of disposal of the deposition defect was incurred.

In a case of the flatness inspection apparatus according to embodiments of the present disclosure and the flatness inspection method using the flatness inspection apparatus, the chuck inspection in step S100, the substrate inspection in step S200, the mask support inspection in step S300, and/or the mask inspection in step S400 may be performed before performing the deposition process.

The flatness inspection apparatus according to an embodiment of the present disclosure and the flatness inspection method using the flatness inspection apparatus may provide for the inspection of, in atmospheric conditions, the flatness of the chuck, the flatness of the substrate (e.g., surface shape) chucked by the chuck, the flatness of the mask support, the amount of sagging of the mask chucked by the chuck (e.g., the surface shape deformed by gravity).

Based on the inspection result, the inspection object may or might not be used in the deposition process. By pre-checking before the deposition process, the reliability of the deposition quality may be increased.

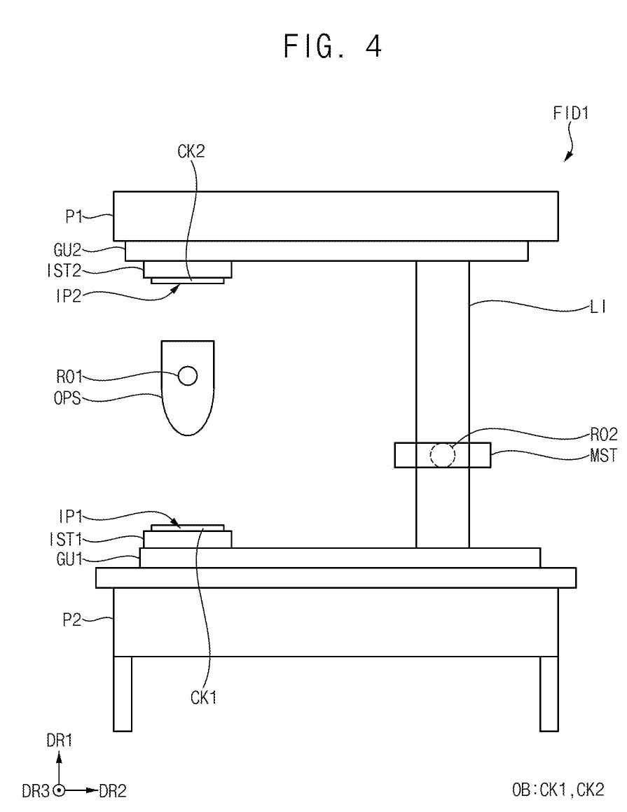

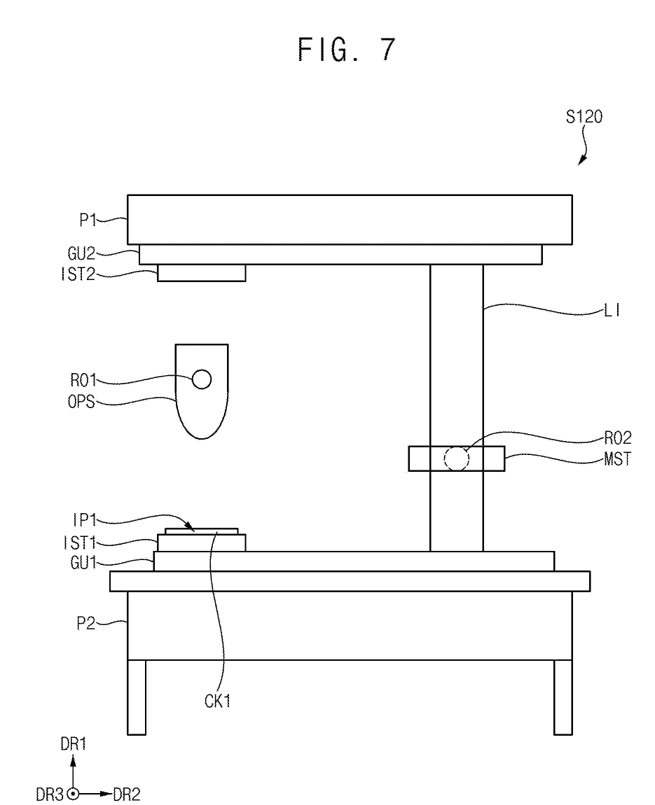

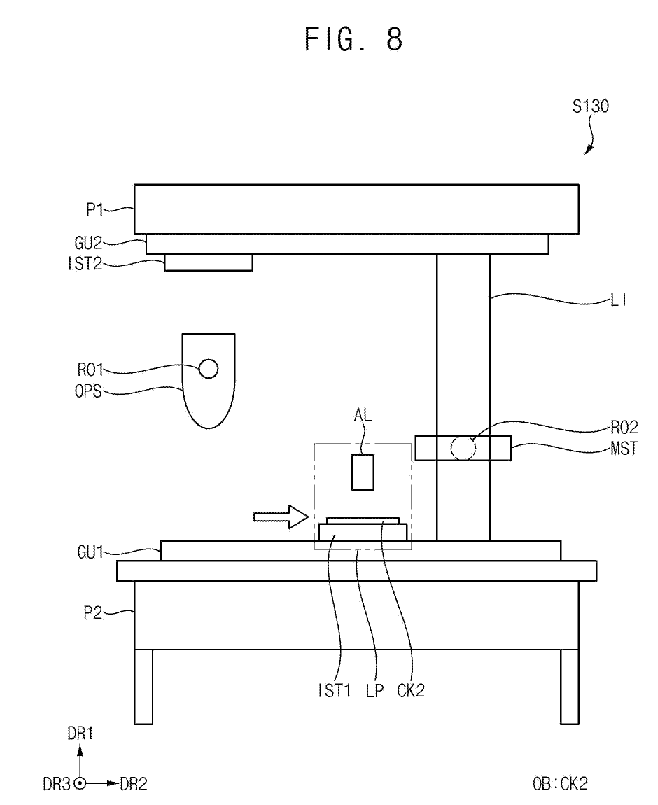

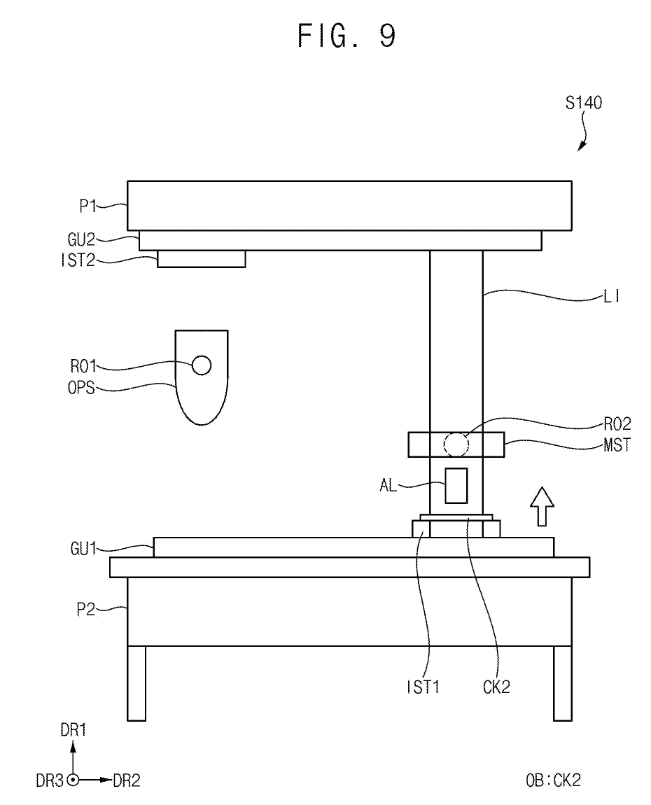

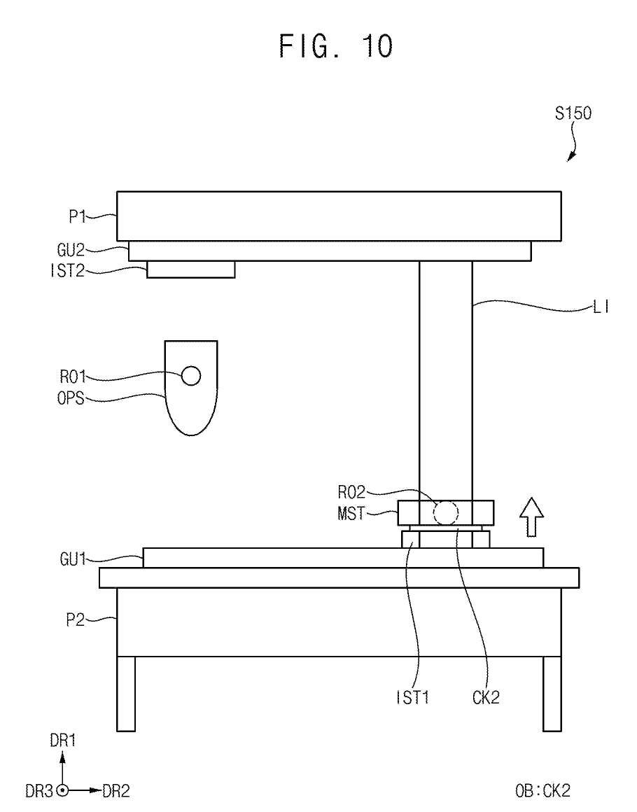

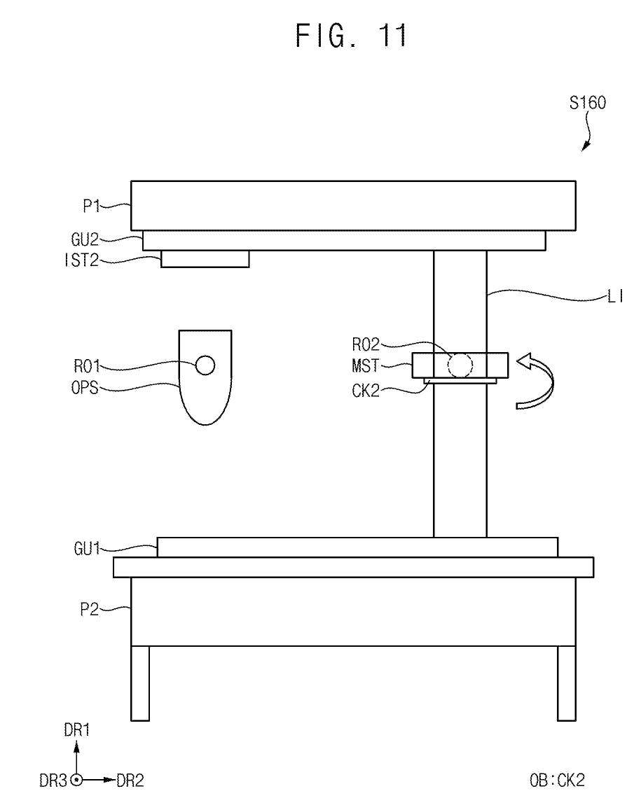

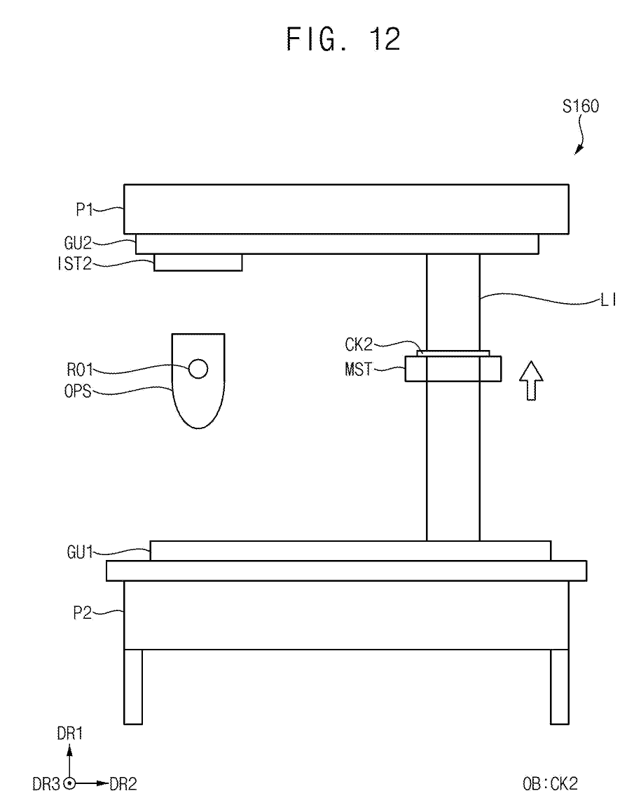

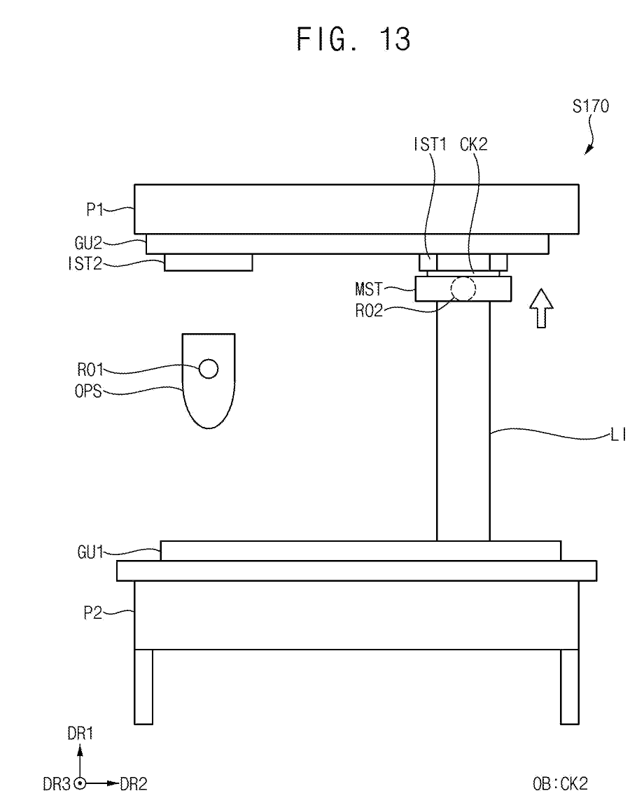

FIGS. 4, 5, 6, 7, 8, 9, 10, 11, 12, 13, 14, 15, 16, 17, 18, 19, 20, 21, 22 and 23, are views illustrating the flatness inspection method according to embodiments of the present disclosure.

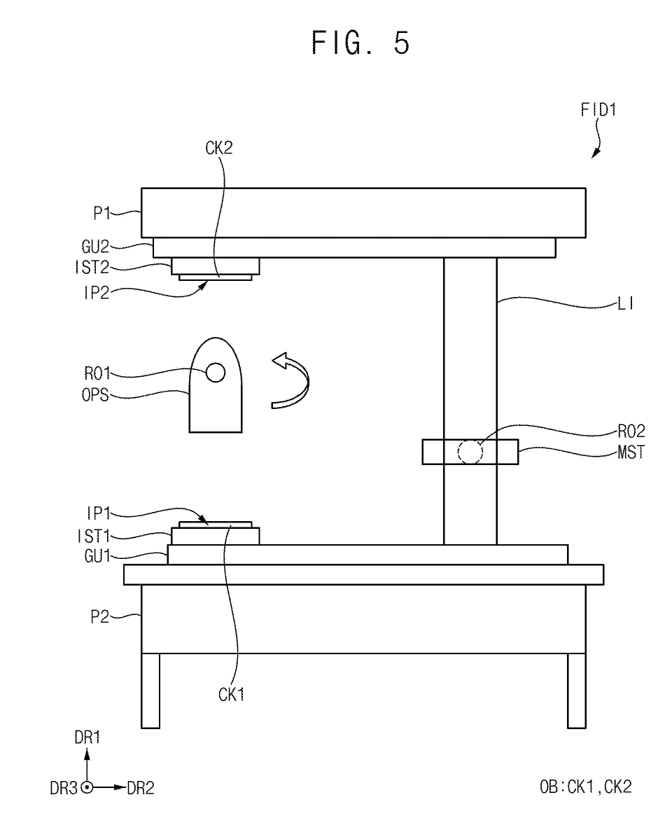

Referring to FIGS. 4 and 5, the flatness inspection apparatus FID1 according to an embodiment may have the non-contact optical system OPS and the transfer stage MST rotated. If the non-contact optical system OPS is in a non-rotated orientation, the non-contact optical system OPS may inspect the inspection object OB at the first inspection position IP1 (e.g., a first chuck CK1) when the non-contact optical system OPS is in an initial orientation (e.g., a first orientation). The non-contact optical system OPS may inspect the inspection object OB at the second inspection position IP2 (e.g., a second chuck CK2).

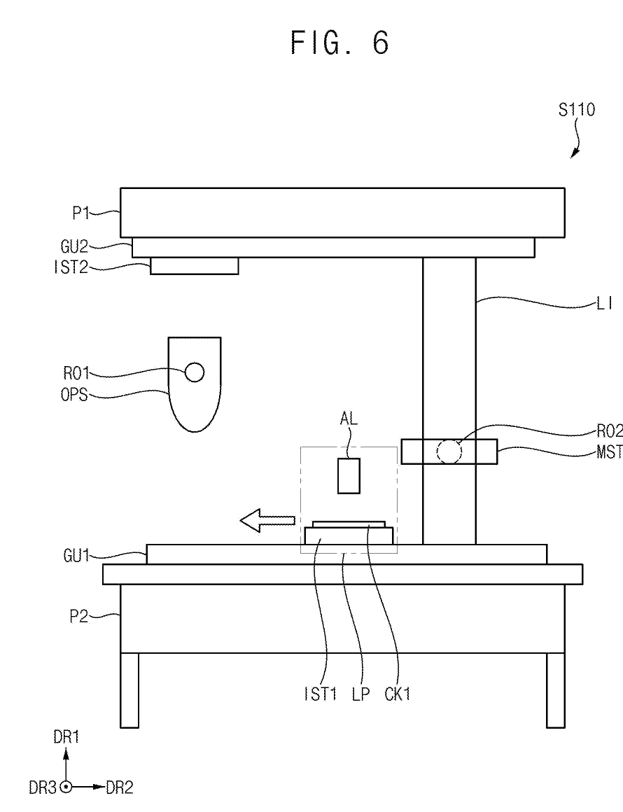

FIGS. 6, 7, 8, 9, 10, 11, 12, 13, 14 and 15, are views illustrating the chuck inspection in step S100 in the flatness inspection method using the flatness inspection apparatus FID1 of FIGS. 1, 2 and 4. Hereinafter, any repetitive detailed descriptions of the same or like elements as those of flatness inspection apparatus FID1 described above will be omitted or simplified for economy of explanation.

Referring to FIGS. 1, 2, 4, 6, 7, 8, 9, 10, 11, 12, 13, 14 and 15, in an embodiment, the first inspection object (e.g., a first chuck CK1) may be placed at the first inspection position. In an embodiment, the step of placing the first inspection object (e.g., the first chuck CK1) at the first inspection position may include placing the first inspection object (e.g., the first chuck CK1) on the first inspection stage IST1 that includes the loading position LP in step S110 and locating the first inspection object (e.g., the first chuck CK1) at the first inspection position IP1 by moving the first inspection stage IST1 in the second direction DR2 intersecting the first direction DR1 in step S120.

For example, in an embodiment the first guide GU1 may be a linear guide. For example, in an embodiment the first inspection stage IST1 may be placed on a rail included in the linear guide. The first inspection stage IST1 may move along the rail in an opposite direction to the second direction DR2 and the second direction DR2. Accordingly, the first inspection stage IST1 may be located at the first inspection position IP1, or may also be located under (e.g., opposite direction to the first direction DR1) the transport stage MST included in the lifter LI which is spaced apart from the first inspection position IP1 in the second direction DR2.

In an embodiment, the non-contact optical system OPS may inspect the surface shape of the first inspection surface of the first inspection object (e.g., the first chuck CK1) at the first inspection position IP1 without contacting the first inspection object. By inspecting the surface shape (e.g., flatness) of the first inspection surface, it is possible to prevent an occurrence of a deposition defect caused by the flatness.

In an embodiment, the second inspection object (e.g., the second chuck CK2) may be placed at the second inspection position. In an embodiment, the step of placing the second inspection object (e.g., the second chuck CK2) at the second inspection position may include placing the second inspection object (e.g., the second chuck CK2) on the first inspection stage IST1 that includes the loading position LP in step S130, locating the first inspection stage IST1 under the transfer stage MST by moving the first inspection stage IST1 in the second direction DR2 in step S140, transferring the second inspection object (e.g., the second chuck CK2) from the first inspection stage IST1 to the transfer stage MST in step S150, flipping over the transfer stage and moving the transfer stage MST in the first direction DR1 in step S160, transferring the second inspection object (e.g., the second chuck CK2) from the flipped over transfer stage MST to the second inspection stage IST2 in step S170, and locating the second inspection object (e.g., the second chuck CK2) at the second inspection position by moving the second inspection stage IST2 in an opposite direction to the second direction DR2 in step S180.

For example, the second guide GU2 may also be a linear guide. For example, the second inspection stage IST2 may be placed on the rail included in the linear guide. The second inspection stage IST2 may move along the rail in the second direction DR2 and in the opposite direction to the second direction DR2. Accordingly, the second inspection stage IST2 may be located at the second inspection position IP2, or may also be located above (e.g., in the first direction DR1) the transport stage MST included in the lifter LI that is spaced apart from the second inspection position IP2 in the second direction DR2.

In an embodiment, the non-contact optical system OPS may inspect the surface shape of the second inspection surface of the second inspection object (e.g., the second chuck CK2) at the second inspection position IP2 without contacting the second inspection object. In an embodiment, the second inspection surface may be deformed by gravity. For example, when inspecting the substrate seated on the second chuck CK2, the second inspection surface may mean a deposition surface on which the deposition process is carried out. By inspecting the surface shape (e.g., flatness) of the first inspection surface, it is possible to prevent an occurrence of a deposition defect caused by the flatness.

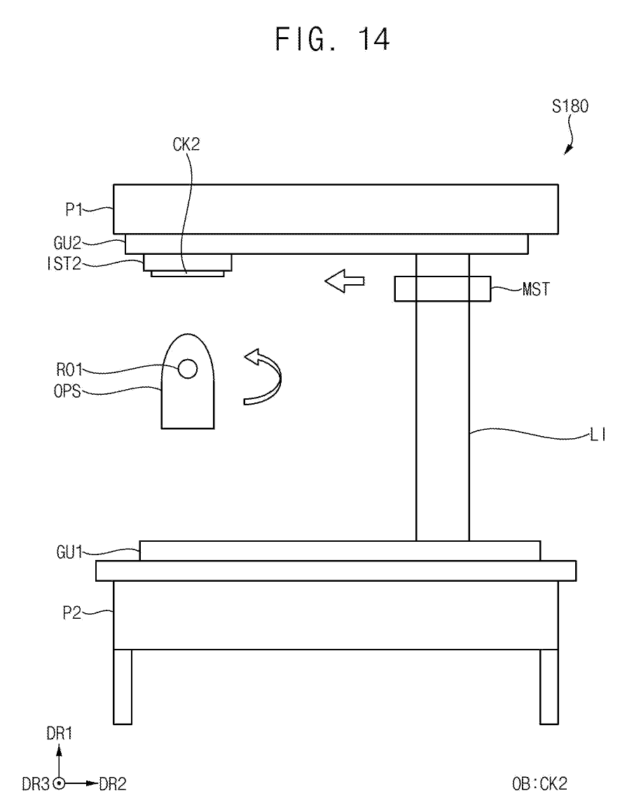

In an embodiment, the non-contact optical system, which has inspected the first inspection object at the first inspection position IP1 without making contact with the first inspection object while the non-contact optical system OPS is in an initial orientation (e.g., a first orientation), may then rotate towards the second inspection position IP2 to be in a second orientation, and inspect the second inspection object at the second inspection position IP2 without making contact with the second inspection object (refer to FIG. 14).

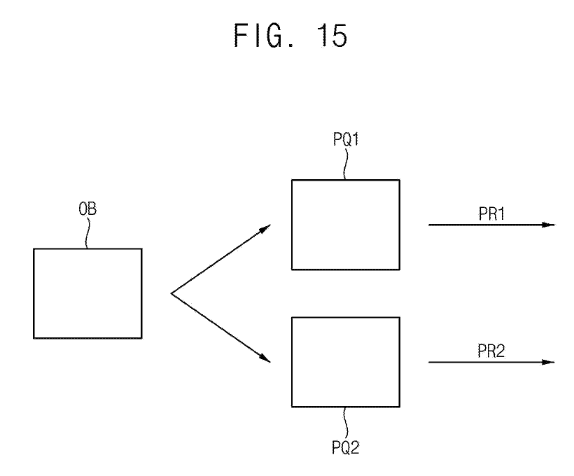

Referring to FIG. 15, it is possible to determine whether the flatness inspection result meets the established criterion, such as a predetermined criterion.

In an embodiment, if the flatness inspection result meets the established criterion (e.g., a predetermined criterion), the inspection object (e.g., the first inspection object and the second inspection object) may be determined to be a good inspected product PQ1. The good inspected product PQ1 may be used in another process in step PR1. For example, the inspection object (e.g., chuck for the substrate), which has been inspected, may be used in another flatness inspection process of another inspection object (e.g., the substrate). For example, the inspection object, which has been inspected, may be used in the following deposition process.

In an embodiment, if the flatness inspection result does not meet the established criterion (e.g., a predetermined criterion), the inspection object OB (e.g., the first inspection object and the second inspection object) may be determined to be a defective inspected object PQ2. The defective inspected object PQ2 may be discarded or subjected to a reprocessing step PR2.

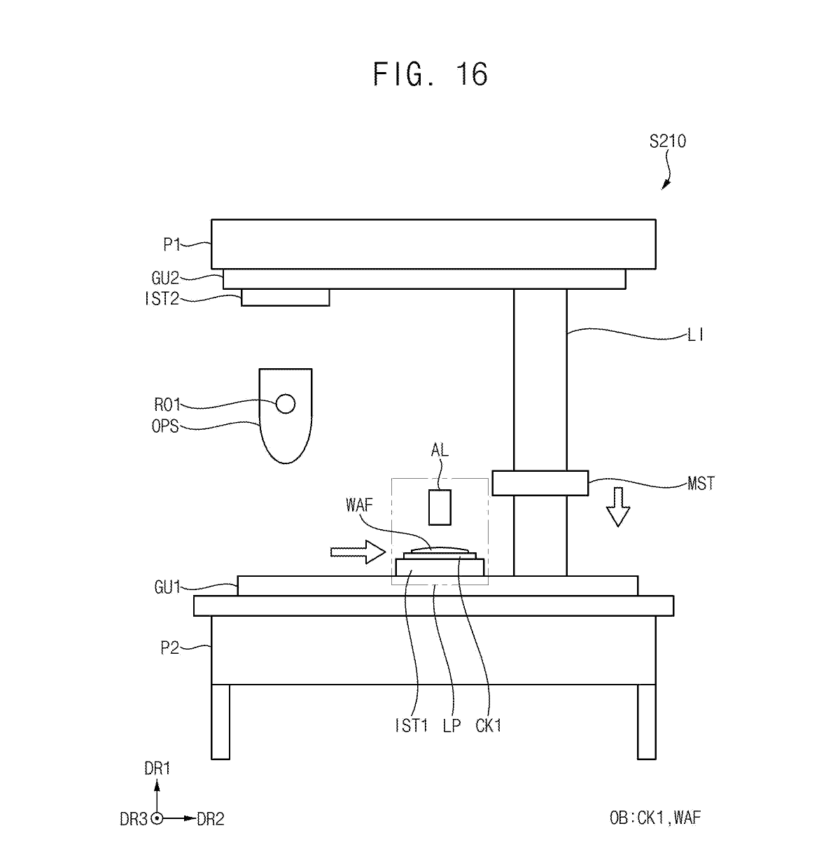

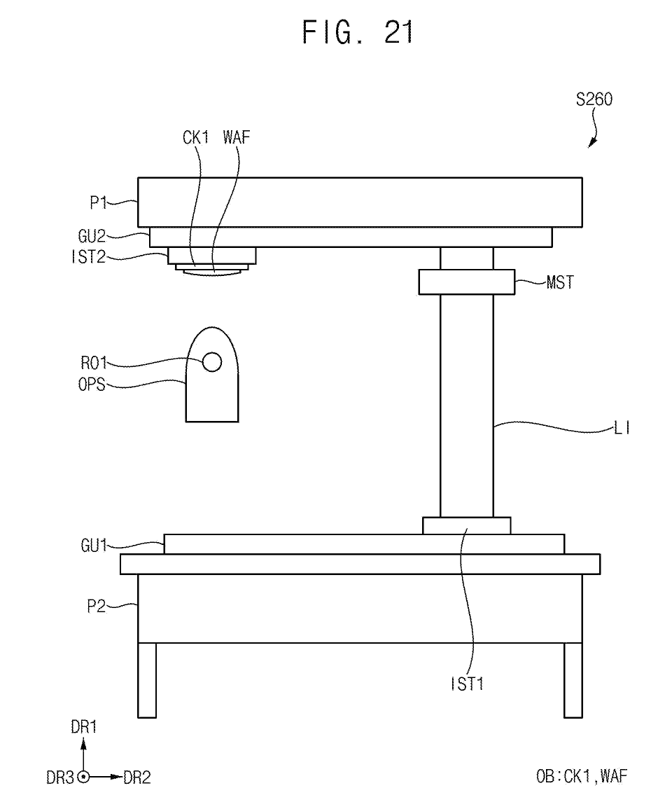

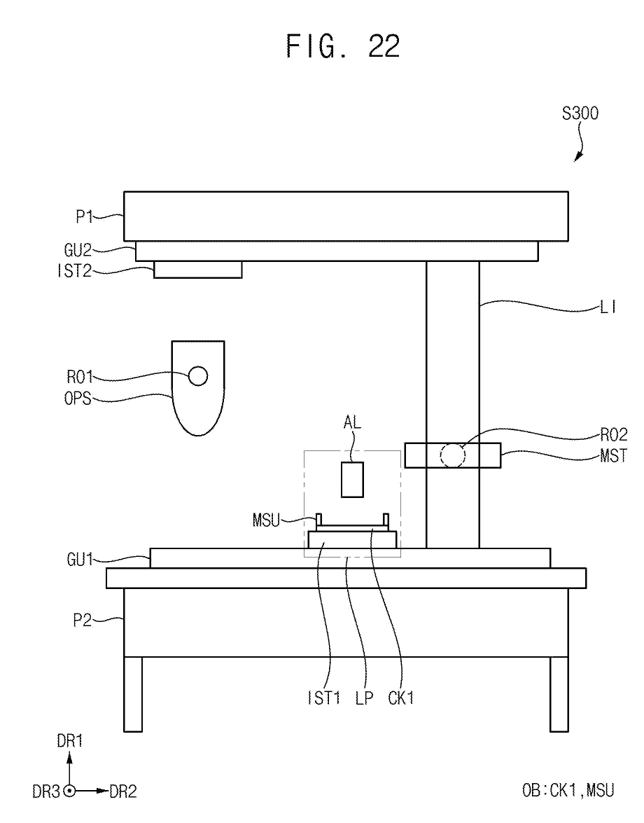

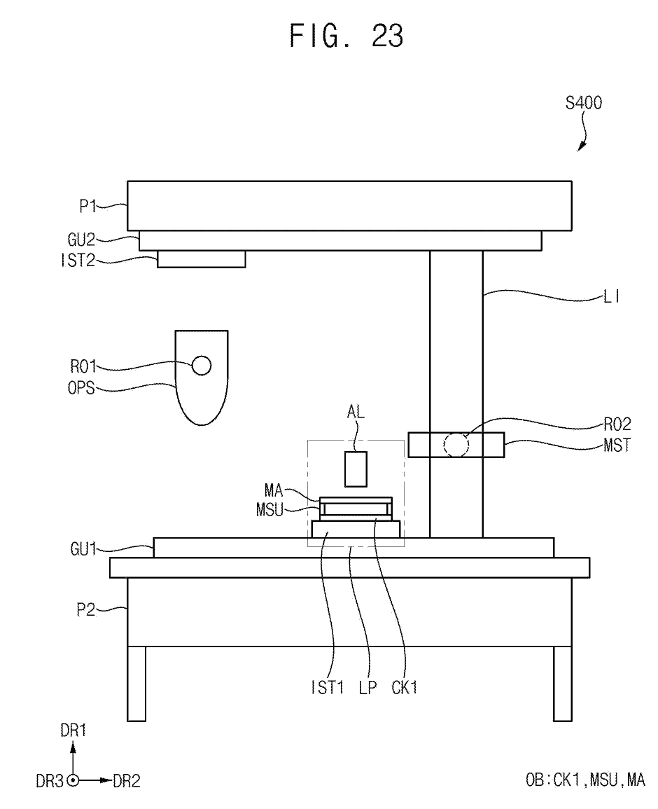

FIGS. 16, 17, 18, 19, 20, and 21 are views illustrating a substrate WAF inspection in step S200 included in the flatness inspection method using the flatness inspection apparatus FID1 of FIGS. 1, 2, and 4. FIG. 22 is a view illustrating a mask support MSU inspection in step S300 included in the flatness inspection method using the flatness inspection apparatus FID1 of FIGS. 1, 2, and 4. FIG. 23 is a view illustrating a mask MA inspection in step S400 included in the flatness inspection method using the flatness inspection apparatus FID1 of FIGS. 1, 2, and 4. Hereinafter, any repetitive detailed descriptions of the same or like elements as those of flatness inspection apparatus FID1 and the chuck inspection S100 described will be omitted or simplified for economy of explanation.

Referring to FIGS. 1, 2, 4, and 16, in an embodiment, the first inspection stage IST1 may be located at the loading position LP. The inspected chuck CK1 may be placed on the first inspection stage IST1 at the loading position LP. The substrate WAF, which is the inspection object OB, may be placed on the inspected chuck CK1 in step S210.

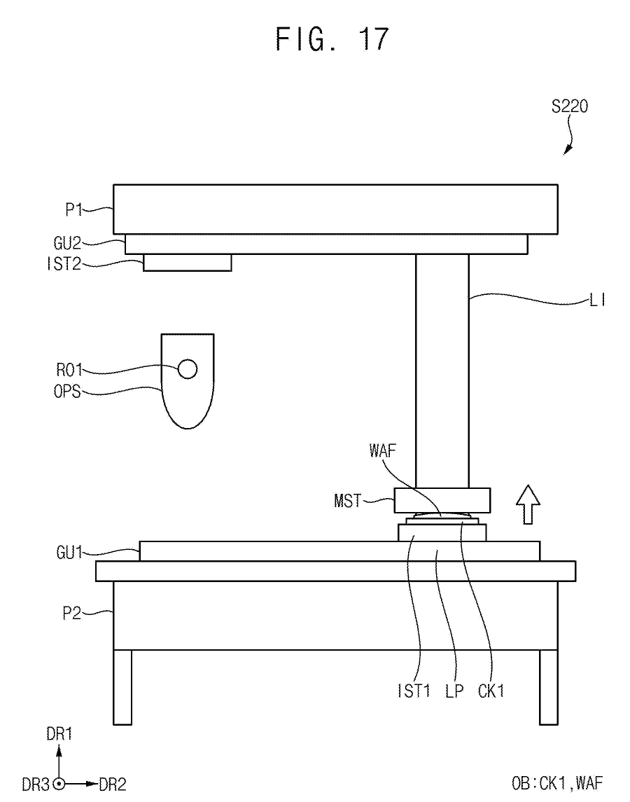

Referring to FIG. 17, the first inspection stage IST1 may be moved in the second direction DR2 to be positioned under the transfer stage MST (e.g., in a direction opposite to the first direction DR1). The substrate WAF may be transferred from the first inspection stage IST1 to the transfer stage MST in step S220.

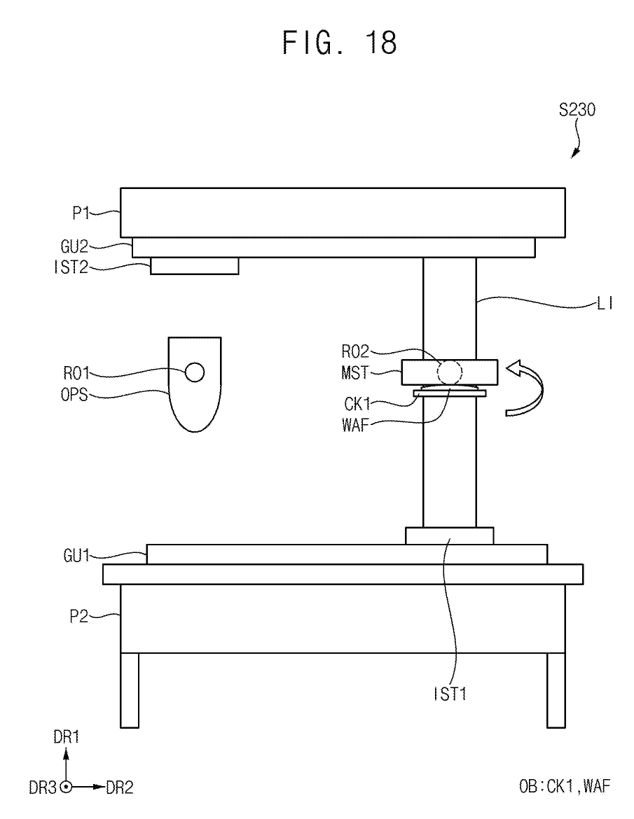

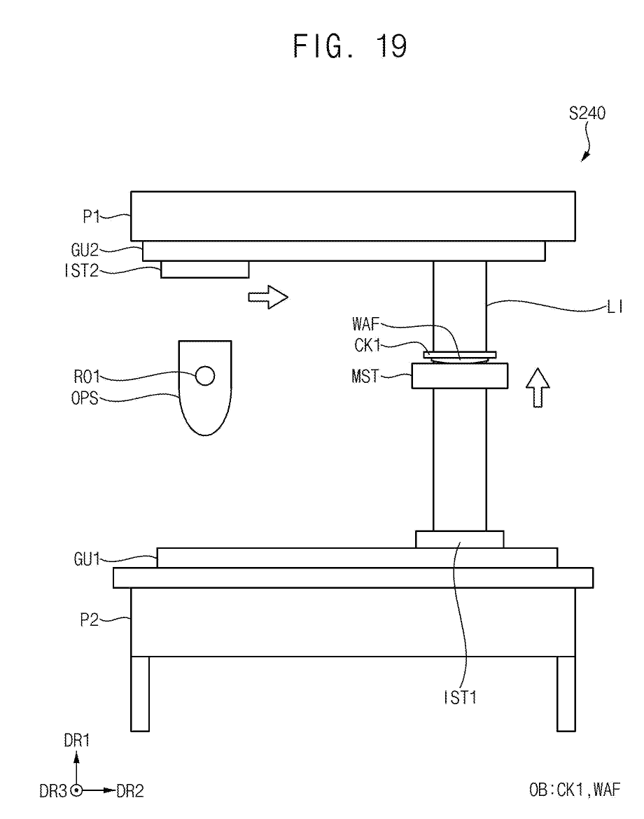

Referring to FIGS. 18 and 19, the transfer stage MST may be flipped over, and the substrate WAF may be moved in the first direction DR1 using the lifter LI in steps S230 and S240.

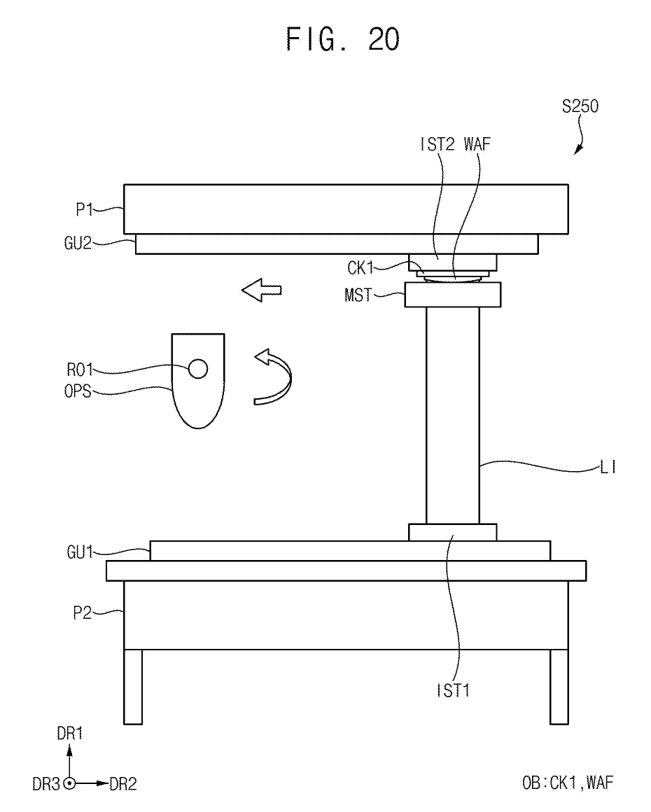

Referring to FIGS. 20 and 21, the substrate WAF may then be transferred to the second inspection stage IST2 in steps S250, S260. The second inspection stage IST2 may be moved in the opposite direction to the second direction DR2 and located at the second inspection position IP2. The non-contact optical system OPS may rotate from a first orientation to a second orientation to inspect the surface shape of the substrate WAF at the second inspection position IP2. The surface shape of the substrate WAF may be the shape that has been deformed by gravitational force at the second inspection position IP2.

Referring to FIGS. 22 and 23, the mask support MSU may be inspected using the inspected object (e.g., the first chuck CK1). The mask MA may be inspected using the inspected object (e.g., the first chuck CK1 and the mask support MSU) which have been inspected in steps S300 and S400. For example, after the inspection object OB may be placed at the loading position LP, the inspection may be performed by moving to the first inspection position IP1.

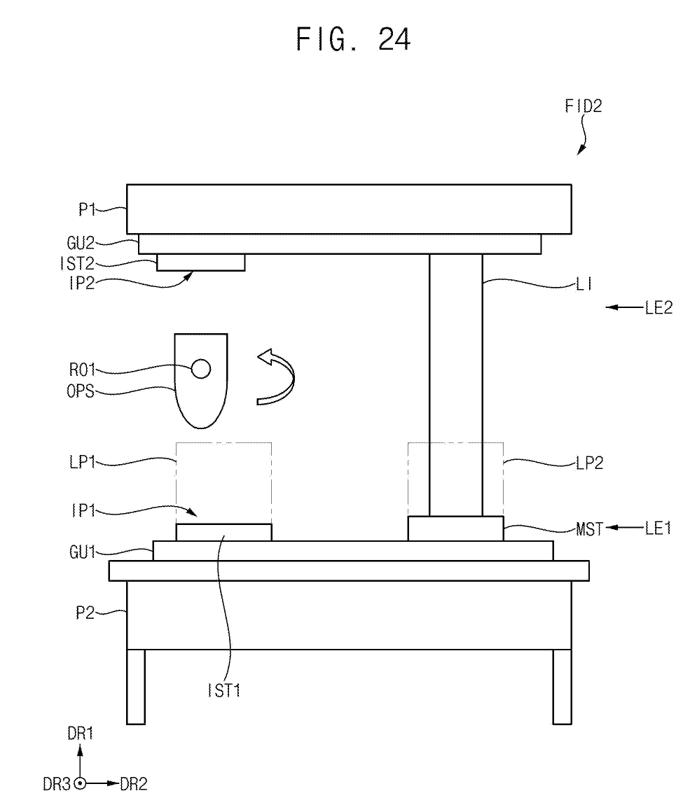

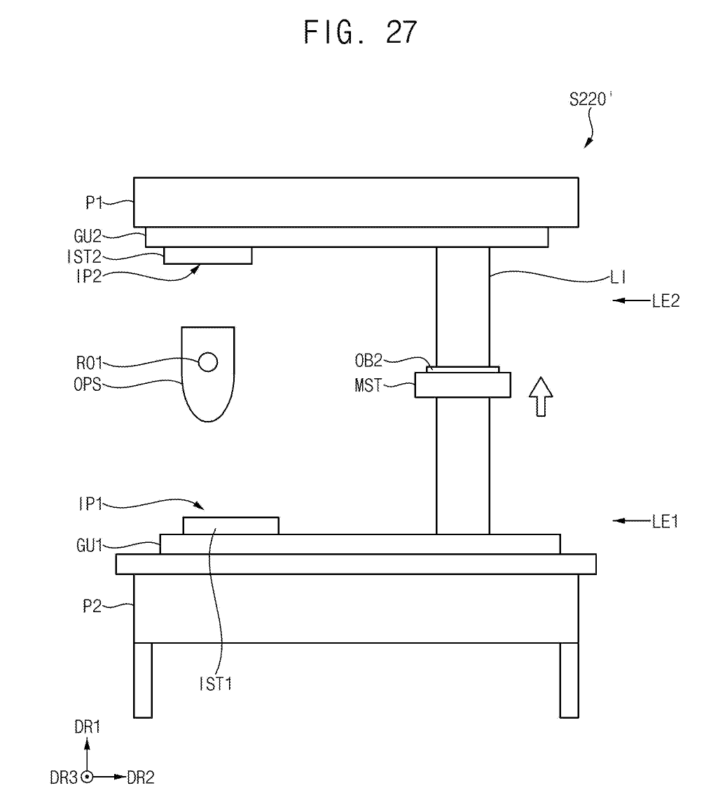

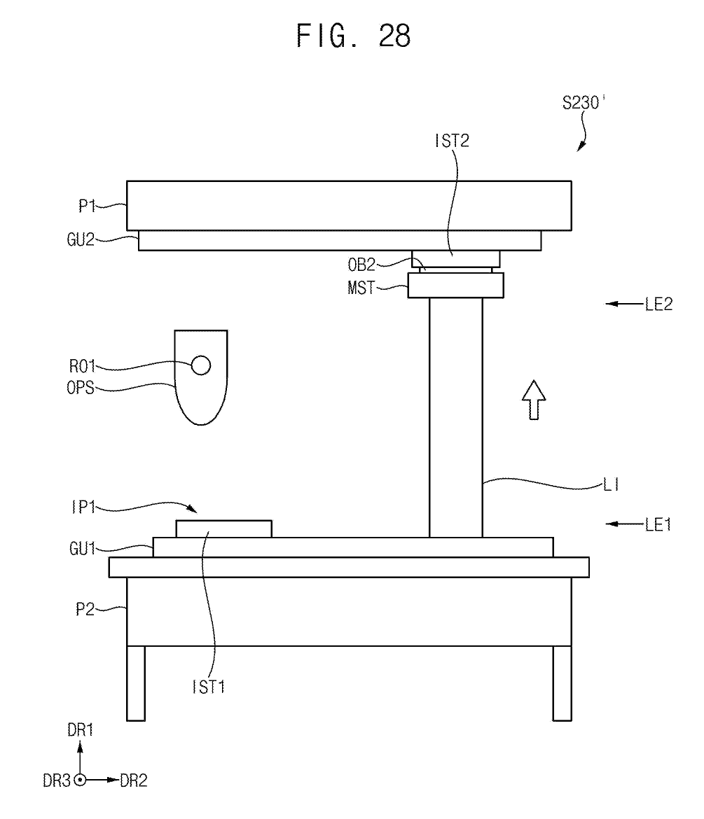

FIG. 24 is a view illustrating a flatness inspection apparatus according to an embodiment of the present disclosure. FIGS. 25, 26, 27, 28, and 29 are views illustrating the flatness inspection method using the flatness inspection apparatus of FIG. 24.

The flatness inspection apparatus FID2 of FIG. 24 may differ only in that the flatness inspection apparatus FID1 of FIGS. 1 and 2 and the transfer stage MST do not rotate and that there are multiple loading positions. Hereinafter, the overlapping descriptions of the flatness inspection apparatus FID1 referring to FIGS. 1 to 23 and the flatness inspection method using the flatness inspection apparatus may be omitted for economy of explanation.

Referring to FIG. 24, in an embodiment, there may be multiple loading positions. For example, in an embodiment the multiple loading positions may include the first loading position LP1 and the second loading position LP2.

Unlike in FIGS. 1 and 2, in an embodiment, the flatness inspection apparatus FID2 of FIG. 24 might not rotate the transfer stage MST. For example, the flatness inspection apparatus FID2 of FIG. 24 might not include the second rotator RO2.

In an embodiment, in the side view, the first loading position LP1 may overlap the first inspection position IP1 (e.g., in the first direction DR1), and the second loading position LP2 may overlap the transfer stage MST (e.g., in the first direction DR1) when the transfer stage MST may be located at a lowest level (e.g., a first level LE1).

Referring to FIG. 25, in an embodiment, the step of placing the first inspection object OB1 at the first inspection position IP1 may include placing the first inspection object OB1 on the first inspection stage IST1 including the first loading position LP1 in step S100’. In an embodiment, a robot arm that places the first inspection object OB1 on the first inspection stage IST1 moves left and right as well as forward and backward movement (e.g., move in the second direction DR2 and the opposite direction to the second direction DR2).

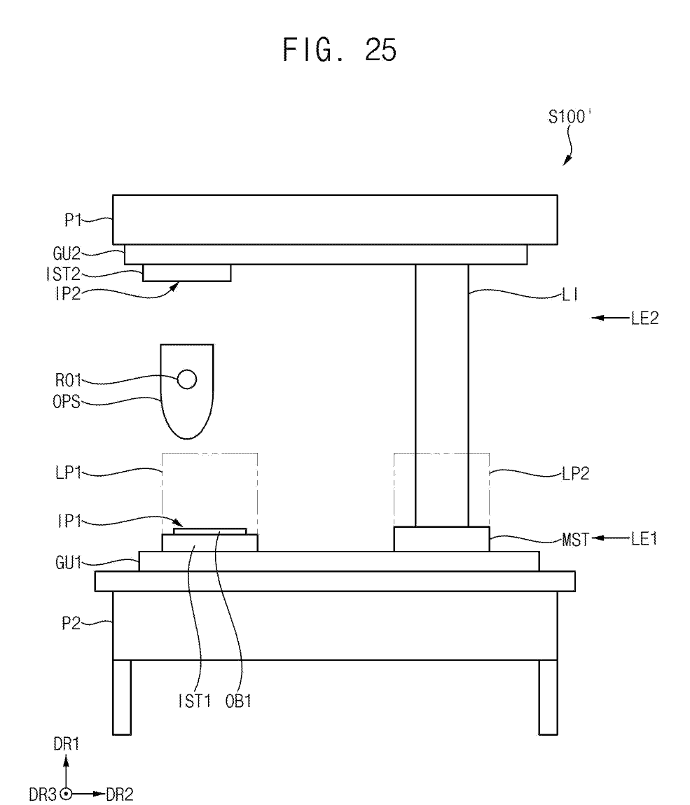

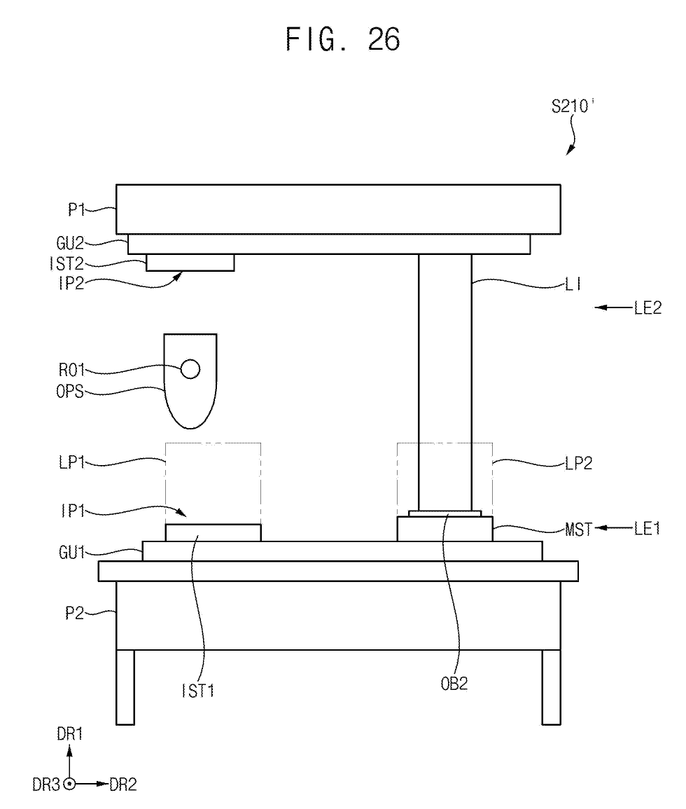

Referring to FIGS. 26, 27, 28 and 29, in an embodiment, the step of placing the second inspection object OB2 to the second inspection position IP2 may include placing the second inspection object OB2 on the transfer stage MST including the second loading position LP2 in step S210’, moving the transfer stage MST in the first direction DR1 in step S220’, transferring the second inspection object OB2 from the transfer stage MST to the second inspection stage IST2 in step S230’ and locating the second inspection stage IST2 at the second inspection position IP2 by moving the second inspection stage IST2 in the opposite direction to the second direction DR2 in step S240’. In the step of transferring the second inspection object OB2 from the transfer stage MST to the second inspection stage IST2 in step S240’, the transfer stage IST2 may be located at a highest level (e.g., a second level LE2). For example, the second level LE2 may be spaced further apart from a ground (e.g., in the first direction DR1) than the first level LE1.

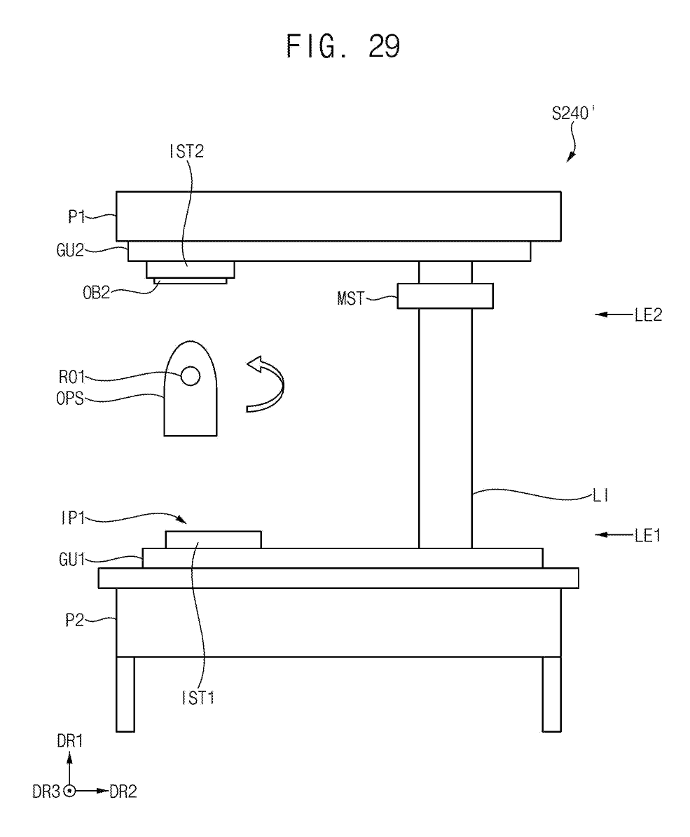

Referring to FIG. 29, in the step of inspecting the surface shape of the second inspection surface in step S240’, the non-contact optical system OPS that inspected the first inspection position IP1 may rotate from a first orientation and face the second inspection position IP2 in a second orientation and then inspect the surface shape of the second inspection object OB2.

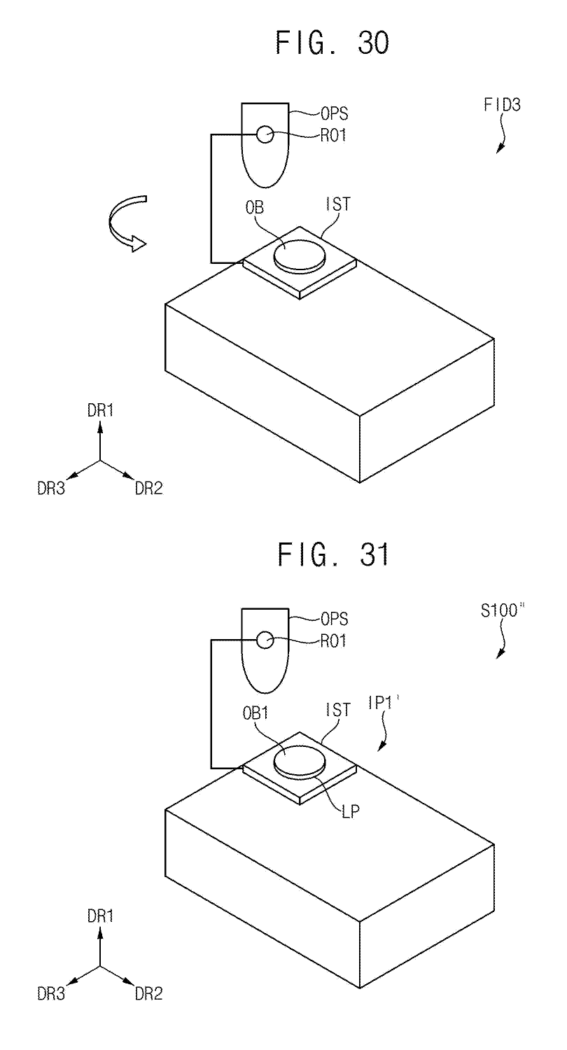

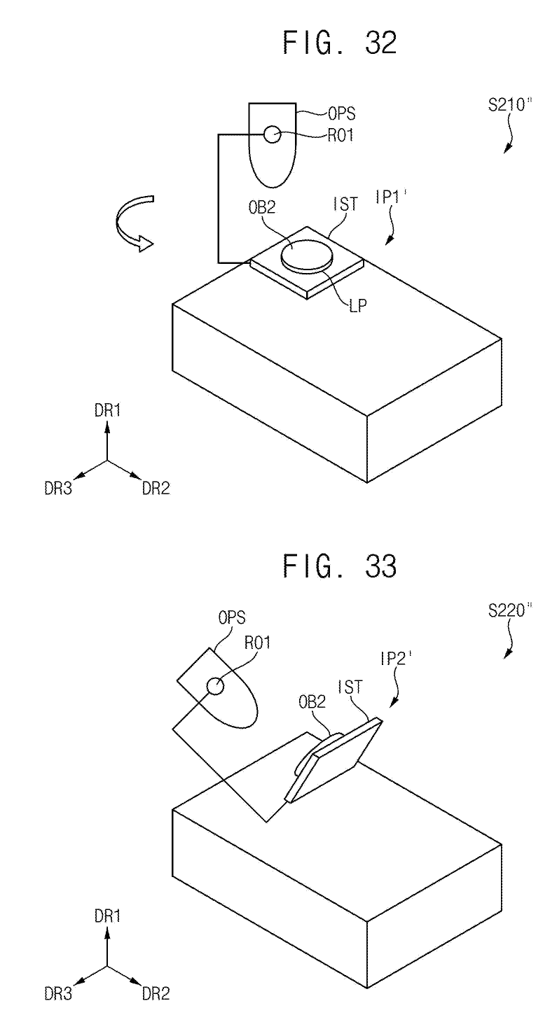

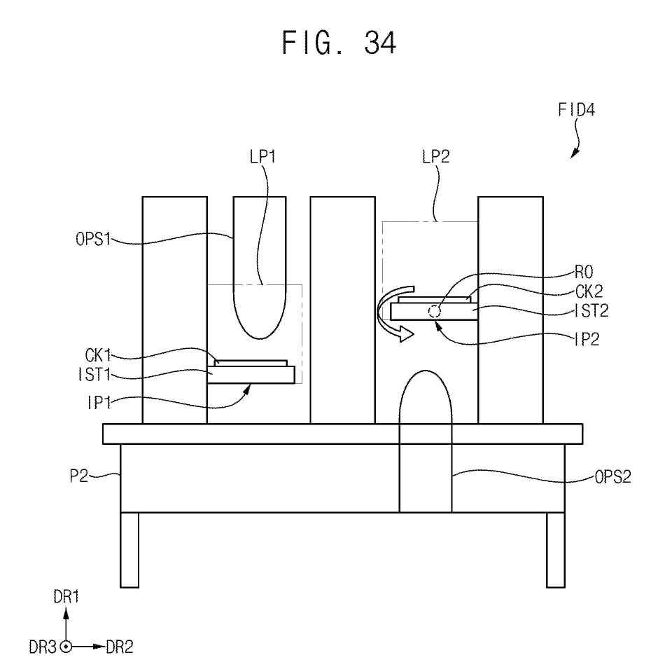

FIG. 30 is a view illustrating a flatness inspection apparatus according to an embodiment of the present disclosure. FIGS. 31, 32, and 33 are views illustrating a flatness inspection method using the flatness inspection apparatus of FIG. 30.

The flatness inspection apparatus FID3 of FIG. 30, unlike the flatness inspection apparatus FID1 of FIGS. 1 and 2 and the flatness inspection apparatus FID2 of FIG. 24, the inspection stage IST may rotate in conjunction with (e.g., together with) the non-contacting optical system OPS. For example, the inspection stage IST may rotate by an angle at which the non-contact optical system OPS rotates. Hereinafter, any repetitive detailed descriptions of the same or like elements as those of flatness inspection apparatus FIDb, FID2 described above with reference to FIGS. 1 to 29 and the flatness inspection method using them will be omitted or simplified for economy of explanation.

Referring to FIGS. 30 and 31, in an embodiment, the inspection stage IST can rotate in conjunction with (e.g., together with) the non-contact optical system OPS. For example, the non-contact optical system OPS and the inspection stage IST may be physically connected to each other. Accordingly, when the non-contact optical system OPS is rotated by the first rotator RO1, the inspection stage IST can also rotate.

In an embodiment, if the non-contact optical system OPS is not rotated and is in a first orientation, the first inspection object OB1 at a first inspection position IP1’ may be inspected in step S100’’. If the inspection stage IST and the non-contact optical system OPS are rotated in step S210’’, the inspection object OB2 may be in a second orientation and the second inspection position IP2’ may be inspected in step S220’’.

In an embodiment, the step of placing the first inspection object OB1 to the first inspection position IP1’ may include placing the first inspection object OB1 on the inspection stage IST that includes the loading position LP. The step of placing the second inspection object OB2 at the second inspection position IP2’ may include placing the second inspection object OB2 on the inspection stage IST that includes the loading position LP in step S210’ and locating the second inspection object OB2 at the second inspection position IP2’ by rotating the inspection stage IST in conjunction with the non-contact optic system OPS in steps S210’ and S220’.

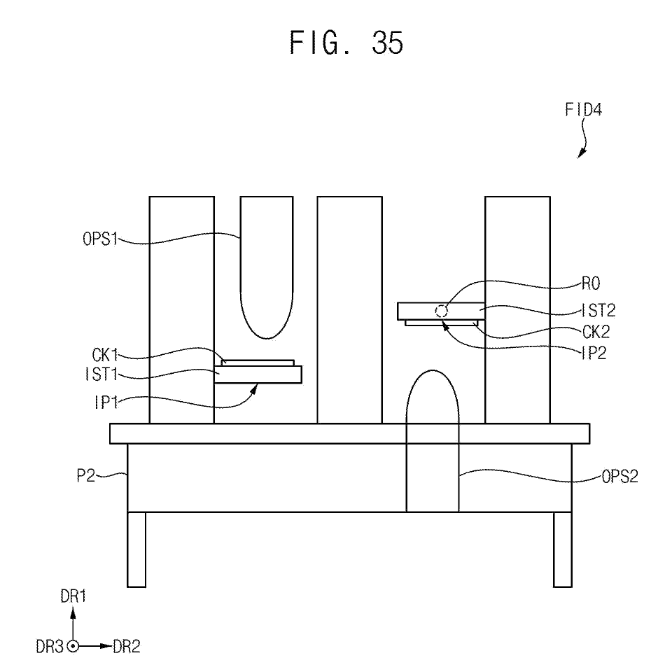

FIGS. 34 and 35 are views illustrating a flatness inspection apparatus according to an embodiment of the present disclosure and a flatness inspection method using the same.

In an embodiment, a flatness inspection apparatus FID4 of FIGS. 34 and 35, unlike the flatness inspection apparatus FID1 of FIGS. 1 and 2, the flatness inspection apparatus FID2 of FIG. 24, and the flatness inspection apparatus FID3 of FIG. 3, may have multiple non-contact optical systems (refer to OPS1, OPS2). Hereinafter, any repetitive detailed descriptions of the same or like elements as those of flatness inspection apparatus FID1, FID2, FID3 described above and the flatness inspection method using them may be omitted or simplified for economy of explanation.

In an embodiment, the flatness inspection apparatus FID4 may include the first inspection stage IST1 including the first inspection position IP1, the second inspection stage IST2 including the second inspection position IP2 facing the first inspection position IP1 in the first direction DR1, a first non-contact optical system OPS1 that inspects the shape of the first inspection surface of the first inspection object (e.g., the first chuck CK1) at the first inspection position IP1, a second non-contact optical system OPS2 that inspects the shape of the second inspection surface of the second inspection object (e.g., the second chuck CK2) deformed by gravity at the second inspection position IP2, and the rotator RO that flip-overs the second inspection stage IST2. While an embodiment shown in FIG. 34 shows the number of the multiple non-contact optical systems of the flatness inspection apparatus FID4 as being two, embodiments of the present disclosure are not necessarily limited thereto and the flatness inspection apparatus FID4 may have three or more non-contact optical systems in some embodiments.

In an embodiment, in the side view, the first loading position LP1 may overlap the first inspection position IP1 (e.g., in the first direction DR1), and the second loading position LP2 may overlap the second inspection stage IST2 (e.g., in the first direction DR1) when it is located at a level prior to being flipped over.

In an embodiment, the second inspection object (e.g., the second chuck CK2) may be located at the second inspection position IP2 by flipping the second inspection stage over IST2.

FIGS. 1 to 35 are examples and embodiments of the present disclosure are not necessarily limited thereto. For example, the number of the optical system, the number of the loading position, whether the optical system rotates, whether the chuck rotates, or the like, may be variously changed.

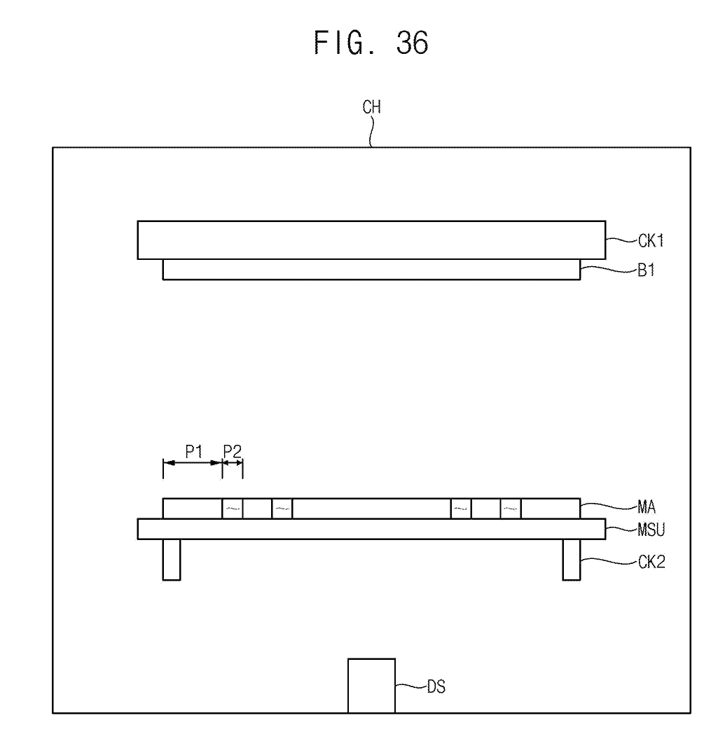

FIG. 36 is a view illustrating the deposition process using the inspected inspection object by the flatness inspection apparatus and the flatness inspection method using the same according embodiments of the present disclosure.

For example, the deposition process may be performed after the flatness inspection process is performed. The deposition process may be performed in a deposition chamber CH.

For example, in an embodiment a deposition source DS, a first chuck CK1, a substrate B1, a mask MA, a mask support SU, and a second chuck CK2 may be placed within the deposition chamber CH.

For example, the first chuck CK1 and the second chuck CK2 may be electrostatic chucks (“ESC”). For example, the electrostatic chuck may be a chuck used in a manufacturing process of a display device and an electronic device including the display device. The electrostatic chuck may use an electric field to fix or move an object (e.g., the substrate B1, the mask MA, or the like). In an embodiment, the electrostatic chuck may hold the object in a non-contact manner to prevent physical damage to the object.

For example, in an embodiment the mask MA may include a fine metal mask (“FMM”), an open metal mask (“SMM”), or the like. The mask MA may be used to deposit a specific pattern on the substrate B1 using the deposition material provided from the deposition source DS. For example, the mask MA may include a first region P1 and a second region P2. The first region P1 is an area through which the deposited material provided from the deposition source DS is impassable. The second region P2 is an area through which the deposited material provided from the deposition source DS can pass.

For example, the mask support MSU may support the mask MA by holding it in place so that the deposited material may be deposited at an exact location.

As described above, in an embodiment, the substrate B1 may be a wafer (corresponding to the WAF of FIGS. 16 to 21). In an embodiment, the silicon wafer may be included in the display device including a light-emitting material, or in an electronic device that includes the display device.

However, embodiments of the present disclosure are not necessarily limited thereto.

For example, the substrate B1 may include glass, plastic, or the like.

In the above, it is explained that the second chuck CK2 and the substrate B1, WAF are inspected at the second inspection position IP2, and the first chuck CK1, mask support MSU and mask MA are inspected at the first inspection position IP1.

By considering the case where the deformation by gravity has not occurred and the case where the deformation by gravity has occurred, the flatness inspection may be carried out under the same conditions as the actual deposition environment. For example, here, it is assumed that the second inspection object (e.g., the second chuck CK2 and the substrate WAF are deformed by the gravity force).

However, embodiments of the present disclosure are not necessarily limited thereto. For example, FIG. 36 takes a horizontal deposition chamber CH as an example, however embodiments of the present disclosure may also be used with a vertical deposition chamber.

For example, if the inspection object OB is deformed by the gravity, it may be inspected at the second inspection position IP2. If the inspection object OB does not experience the gravitational deflection (or gravitational deflection is at a negligible level), it may only be inspected at the first inspection position IP1. For example, if the deposition chamber CH is of the vertical type, the second chuck CK2, the substrate B1, WAF, the first chuck CK1, the mask support MSU and the mask MA may all be deformed by gravity. Accordingly, the inspection object OB may be flatness inspected at the second inspection position IP2, to perform the flatness inspection in an environment identical to an actual deposition environment.

The display device according to one or more embodiments may be applied to a variety of electronic devices. The electronic apparatus according to one or more embodiments includes the aforementioned display device and may include a module or apparatus having other additional functions in addition to the display device.

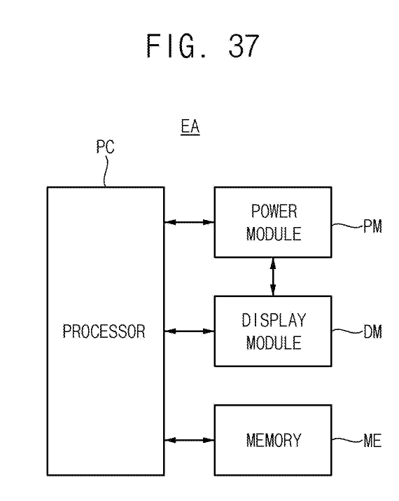

FIG. 37 is a block diagram illustrating an electronic device according to an embodiment.

Referring to FIG. 37, an electronic device EA according to an embodiment may include a display module DM, a processor PC, a memory ME, and a power module PM.

The processor PC may include a central processing unit (“CPU”), an application processor (“AP”), a graphic processing unit (“GPU”), a communication processor (“CP”), an image signal processor (“ISP”), and/or a controller.

Data information necessary for operation of the processor PC or the display module DM may be stored in the memory ME. When the processor PC executes an application stored in the memory ME, an image data signal and/or an input control signal is transmitted to the display module DM, and the display module DM may process received signal and output image information through a display screen.

The power module PM may include a power supply module such as a power adapter and/or a battery device, and a power conversion module that converts power supplied by the power supply module to generate power desired or required for operation of the electronic device EA.

At least one of the components of the electronic device EA described above may be included in the display device according to the above-described embodiments. In addition, some of individual modules functionally included in one module may be included in the display device, and others may be provided separately from the display device. For example, the display device may include the display module DM, and the processor PC, the memory ME, and the power module PM may be provided in the form of another device in the electronic device EA other than the display device.

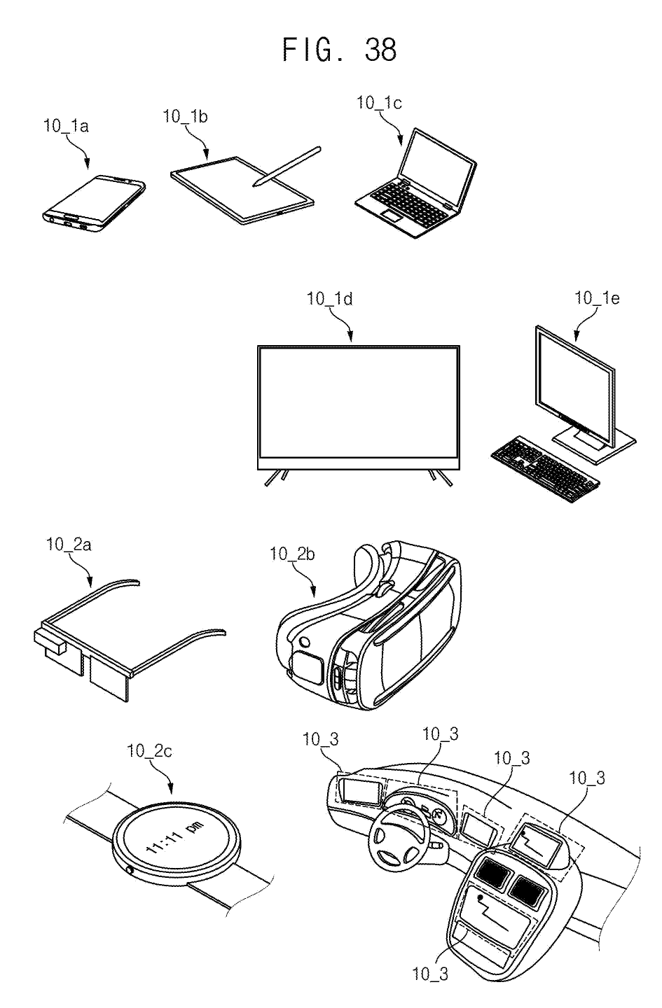

FIG. 38 is a schematic diagram of an electronic device according to an embodiment.

Referring to FIG. 38, one or more suitable electronic devices to which display devices according to one or more embodiments are applied may include not only electronic devices for image display such as a smartphone 10_1a, a tablet PC 10_1b, a laptop 10_1c, a TV 10_1d, a desk monitor 10_1e, and/or the like, but wearable electronic devices including display modules such as a smart glass 10_2a, a head mounted display 10_2b, a smart watch 10_2c, and/or the like, vehicle electronic device 10_3 including display modules such as on a vehicle's instrument panel, a center fascia, a center information display (“CID”) located on a dashboard, a room mirror display, and/or the like. However, embodiments of the present disclosure are not necessarily limited hereto and the display devices may be applied to various different small-sized, medium-sized and large-sized display devices.

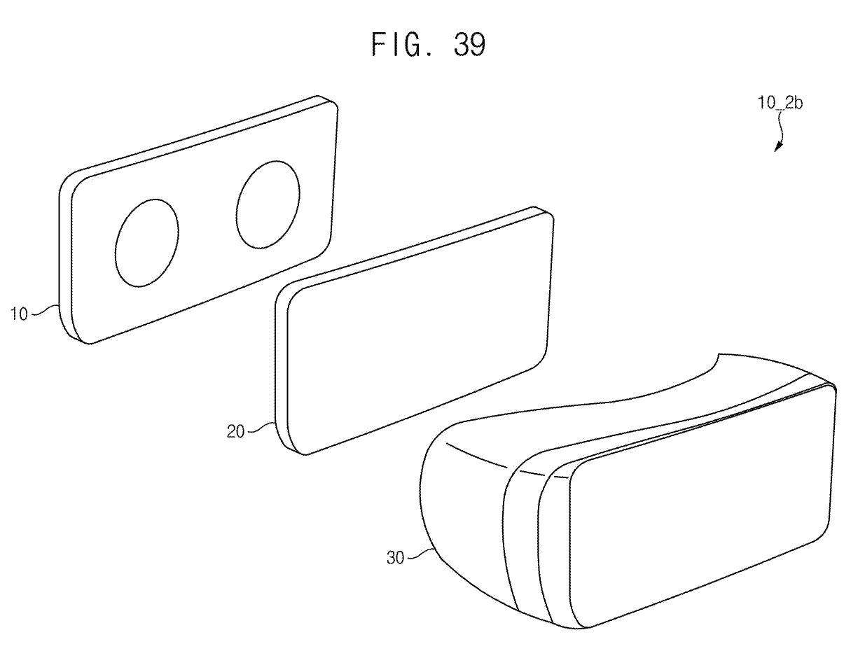

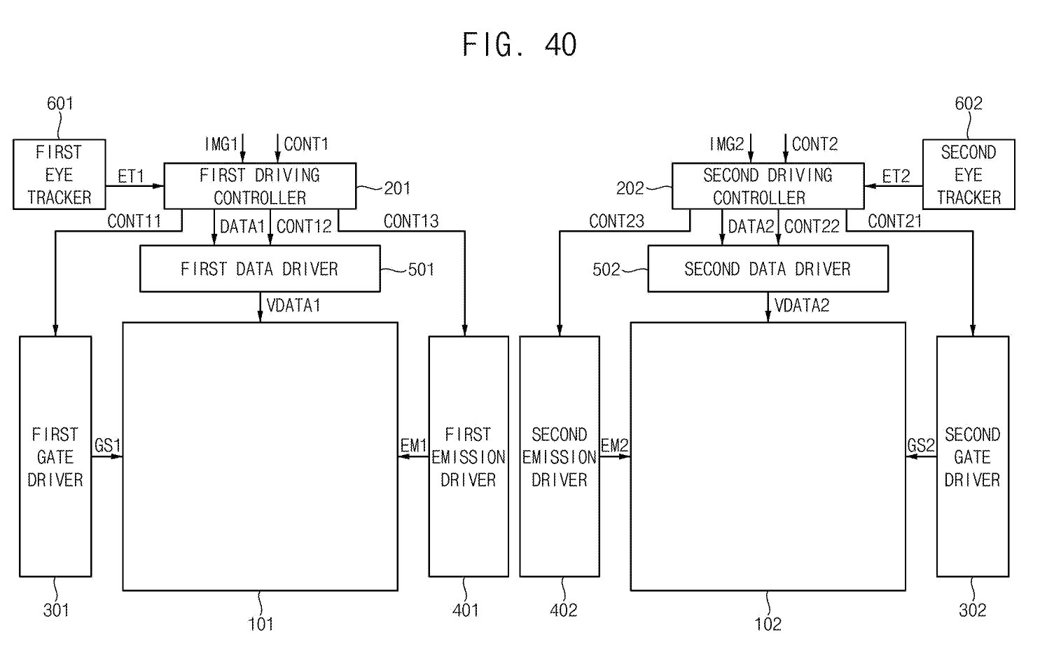

FIG. 39 is a view illustrating a display device according to an embodiment of the present disclosure.

Referring to FIG. 39, the display device may include a lens 10, a display module 20 and a housing 30. The display module 20 may be located adjacent to the lens 10. The housing 30 may receive the lens 10 and the display module 20. Although the lens unit 10 and the display module 20 are received on a first side of the housing 30 in FIG. 39, embodiments according to the present disclosure are not necessarily limited thereto.

For example, the lens 10 may be received on a first side of the housing 30 and the display module 20 may be received on a second side of the housing 30 opposite to the first side of the housing 30. When the lens 10 and the display device are received on opposite sides with respect to the housing 30, the housing 30 may have a transmitting portion to transmit a light.

For example, the display device may be a head mounted display device worn on a user’s head. According to some embodiments, the head mounted display device may further include a head band to fix the display device to the user’s head.

However, embodiments of the present disclosure are not necessarily limited thereto. For example, in FIG. 39, the display device has been described as being implemented as the head-mounted display 10_2b of FIG. 38, however, the present disclosure is not limited thereto.

For example, the display device may have a form of smart glasses designed as a shape of glasses. For example, the display device may be implemented as a virtual reality (“VR”) display device for supporting a virtual reality.

In addition, the display device may be implemented as an augmented reality (“AR”) display device for supporting an augmented reality. The AR display device may have a smartphone shape, a smart glasses shape, a head mounted display shape, etc., but embodiments according to the present disclosure are not necessarily limited to those shapes.

In addition, the display device may be implemented as a mixed reality (“MR”) display device for supporting a mixed reality. The MR display device may have a smartphone shape, a smart glasses shape, a head mounted display shape, etc., but embodiments according to the present disclosure are not necessarily limited to those shapes.

The display module 20 may include a first display panel. The first display panel may be a left-eye display panel corresponding to a left eye of the user.

The display module 20 may include a second display panel. The second display panel may be a right-eye display panel corresponding to a right eye of the user.

The lens 10 may include a left-eye lens corresponding to the left-eye display panel and a right-eye lens corresponding to the right-eye display panel.

FIG. 40 is a block diagram illustrating the display device of FIG. 39.

Referring to FIGS. 39 and 40, the display device includes a display panel 101, an eye tracker 601 and a display panel driver. The display panel driver drives the display panel 101. The display panel driver includes a driving controller 201, a gate driver 301, an emission driver 401 and a data driver 501.

The display panel 101, the eye tracker 601, the driving controller 201, the gate driver 301, the emission driver 401 and the data driver 501 may be referred to as a first display panel 101, a first eye tracker 601, a first driving controller 201, a first gate driver 301, a first emission driver 401 and a first data driver 501, respectively. For example, the first display panel 101 may be the left-eye display panel corresponding to the left eye of the user.

For example, the driving controller 201 and the data driver 501 may be integrally formed. A driving module including at least the driving controller 201 and the data driver 501 which are integrally formed may be referred to as a timing controller embedded data driver (TED).

The display panel 101 has a display region at which images are displayed and a peripheral region adjacent to the display region.

The display panel 101 includes a plurality of gate lines, a plurality of data lines, a plurality of emission lines and a plurality of pixels electrically connected to the gate lines, the data lines and the emission lines. The gate lines may extend in a first direction, the data lines may extend in a second direction crossing the first direction and the emission lines may extend in the first direction.

The driving controller 201 receives input image data IMG1 and an input control signal CONT1 from an external apparatus (e.g. a host, a set apparatus or an application processor). For example, the input image data IMG1 may include red image data, green image data and blue image data. For example, the input image data IMG1 may include white image data. For example, the input image data IMG1 may include magenta image data, yellow image data and cyan image data. The input control signal CONT1 may include a master clock signal and a data enable signal. The input control signal CONT1 may further include a vertical synchronizing signal and a horizontal synchronizing signal.

The driving controller 201 generates a first control signal CONT11, a second control signal CONT12, a third control signal CONT13 and a data signal DATA1 based on the input image data IMG1 and the input control signal CONT1.

The driving controller 201 generates the first control signal CONT11 for controlling an operation of the gate driver 301 based on the input control signal CONT1, and outputs the first control signal CONT11 to the gate driver 301. The first control signal CONT11 may include a vertical start signal and a gate clock signal.

The driving controller 201 generates the second control signal CONT12 for controlling an operation of the data driver 501 based on the input control signal CONT1, and outputs the second control signal CONT12 to the data driver 501. The second control signal CONT12 may include a horizontal start signal and a load signal.

The driving controller 201 generates the data signal DATA1 based on the input image data IMG1. The driving controller 201 outputs the data signal DATA1 to the data driver 501.

The driving controller 201 generates the third control signal CONT13 for controlling an operation of the emission driver 401 based on the input control signal CONT1, and outputs the third control signal CONT13 to the emission driver 401.

The gate driver 301 generates gate signals GS1 driving the gate lines in response to the first control signal CONT11 received from the driving controller 201. The gate driver 301 outputs the gate signals GS1 to the gate lines. For example, the gate driver 301 may sequentially output the gate signals GS1 to the gate lines. For example, the gate driver 301 may be mounted on the peripheral region of the display panel 101. For example, the gate driver 301 may be integrated on the peripheral region of the display panel 101.

The emission driver 401 generates emission signals EM1 driving the emission lines in response to the third control signal CONT13 received from the driving controller 201. The emission driver 401 outputs the emission signals EM1 to the emission lines. For example, the emission driver 401 may sequentially output the emission signals EM1 to the emission lines. For example, the emission driver 401 may be mounted on the peripheral region of the display panel 101. For example, the emission driver 401 may be integrated on the peripheral region of the display panel 101.

Although the gate driver 301 is located at a first side of the display panel 101 and the emission driver 401 is located at a second side of the display panel 101 opposite to the first side in FIG. 40 for convenience of explanation, embodiments according to the present disclosure are not necessarily limited thereto. For example, both of the gate driver 301 and the emission driver 401 may be located at the first side of the display panel 101. For example, both of the gate driver 301 and the emission driver 401 may be located at both sides of the display panel 101. For example, the gate driver 301 and the emission driver 401 may be integrally formed.

The data driver 501 may receive the second control signal CONT12 and the data signal DATA1 from the driving controller 201. The data driver 501 may convert the data signal DATA1 into data voltages VDATA1 having an analog type. The data driver 501 outputs the data voltages VDATA1 to the data lines.

The eye tracker 601 may track a view of the user. For example, the eye tracker 601 may track a view of the left eye of the user. The eye tracker 601 may output a view signal ET1 to the driving controller 201.

In the present embodiments, the display panel driver may determine a central viewing area of the display panel 101 and a peripheral viewing area of the display panel 101 based on the view of the user, drive the central viewing area of the display panel 101 at a first duty ratio and drive the peripheral viewing area of the display panel 101 at a second duty ratio. The first duty ratio is less than the second duty ratio.

The display device includes a second display panel 102, a second eye tracker 602 and a second display panel driver. The second display panel driver drives the second display panel 102. The second display panel driver includes a second driving controller 202, a second gate driver 302, a second emission driver 402 and a second data driver 502.

For example, the second display panel 102 may be the right-eye display panel corresponding to the right eye of the user.

For example, the second driving controller 202 and the second data driver 502 may be integrally formed. A driving module including at least the second driving controller 202 and the second data driver 502 which are integrally formed may be referred to as a second timing controller embedded data driver (“TED”).

The second display panel 102 has a display region on which an image is displayed and a peripheral region adjacent to the display region.

The second display panel 102 includes a plurality of second gate lines, a plurality of second data lines, a plurality of second emission lines and a plurality of second pixels electrically connected to the second gate lines, the second data lines and the second emission lines. The second gate lines may extend in the first direction, the second data lines may extend in the second direction and the second emission lines may extend in the first direction.

The second driving controller 202 receives second input image data IMG2 and a second input control signal CONT2 from an external apparatus (e.g. a host, a set apparatus or an application processor). For example, the second input image data IMG2 may include red image data, green image data and blue image data. For example, the second input image data IMG2 may include white image data. For example, the second input image data IMG2 may include magenta image data, yellow image data and cyan image data. The second input control signal CONT2 may include a master clock signal and a data enable signal. The second input control signal CONT2 may further include a vertical synchronizing signal and a horizontal synchronizing signal.

The second driving controller 202 generates a 2-1 control signal CONT21, a 2-2 control signal CONT22, a 2-3 control signal CONT23 and a second data signal DATA2 based on the second input image data IMG2 and the second input control signal CONT2.

The second driving controller 202 generates the 2-1 control signal CONT21 for controlling an operation of the second gate driver 302 based on the second input control signal CONT2, and outputs the 2-1 control signal CONT21 to the second gate driver 302. The 2-1 control signal CONT21 may include a second vertical start signal and a second gate clock signal.

The second driving controller 202 generates the 2-2 control signal CONT22 for controlling an operation of the second data driver 502 based on the second input control signal CONT2, and outputs the 2-2 control signal CONT22 to the second data driver 502. The 2-2 control signal CONT22 may include a second horizontal start signal and a second load signal.

The second driving controller 202 generates the second data signal DATA2 based on the second input image data IMG2. The second driving controller 202 outputs the second data signal DATA2 to the second data driver 502.

The second driving controller 202 generates the 2-3 control signal CONT23 for controlling an operation of the second emission driver 402 based on the second input control signal CONT2, and outputs the 2-3 control signal CONT23 to the second emission driver 402.

The second gate driver 302 generates second gate signals GS2 driving the second gate lines in response to the 2-1 control signal CONT21 received from the second driving controller 202. The second gate driver 302 outputs the second gate signals GS2 to the second gate lines. For example, the second gate driver 302 may sequentially output the second gate signals GS2 to the second gate lines. For example, the second gate driver 302 may be mounted on the peripheral region of the second display panel 102. For example, the second gate driver 302 may be integrated on the peripheral region of the second display panel 102.

The second emission driver 402 generates second emission signals EM2 driving the second emission lines in response to the 2-3 control signal CONT23 received from the second driving controller 202. The second emission driver 402 outputs the second emission signals EM2 to the second emission lines. For example, the second emission driver 402 may sequentially output the second emission signals EM2 to the second emission lines. For example, the second emission driver 402 may be mounted on the peripheral region of the second display panel 102. For example, the second emission driver 402 may be integrated on the peripheral region of the second display panel 102.

Although the second gate driver 302 is located at a first side of the second display panel 102 and the second emission driver 402 is located at a second side of the second display panel 102 opposite to the first side in FIG. 40 for convenience of explanation, embodiments according to the present disclosure are not necessarily limited thereto. For example, both of the second gate driver 302 and the second emission driver 402 may be located at the first side of the second display panel 102. For example, both of the second gate driver 302 and the second emission driver 402 may be located both sides of the second display panel 102. For example, the second gate driver 302 and the second emission driver 402 may be integrally formed.

The second data driver 502 may receive the 2-2 control signal CONT22 and the second data signal DATA2 from the second driving controller 202. The second data driver 502 may convert the second data signal DATA2 into second data voltages VDATA2 having an analog type. The second data driver 502 outputs the second data voltages VDATA2 to the second data lines.

The second eye tracker 602 may track a second view of the user. For example, the second eye tracker 602 may track a view of the right eye of the user. The second eye tracker 602 may output a second view signal ET2 to the second driving controller 202.

The second eye tracker 602 is capable of tracking the user’s second field of view. For example, the second eye tracker 602 can track the vision of the user’s right eye. The second eye tracker 602 may output a second field of view signal ET2 to the second drive controller 202.

The flatness inspection apparatus according to embodiments may be applied to a manufacturing process of various display devices included in a computer, a notebook, a cell phone, a smart phone, a smart phone, a PMP, a PDA, or a MP3 player.

The above description is an example of technical features of the present disclosure, and those skilled in the art to which the present disclosure pertains will be able to make various modifications and variations. Thus, embodiments of the present disclosure described herein may be implemented separately or in combination with each other. Embodiments disclosed in the present disclosure are examples, and are not limiting on the technical spirit of the present disclosure. Embodiments describe the technical spirit of the present disclosure, and do not limit the scope of the technical spirit of the present disclosure. Therefore, it is to be understood that the foregoing is illustrative of various embodiments and is not to be construed as limiting, and that modifications to embodiments, as well as other embodiments, are intended to be included within the scope of the present disclosure.

What is claimed is:

1. A flatness inspection apparatus comprising:
an inspection stage having a first inspection position and a second inspection position, the second inspection position facing the first inspection position in a first direction;
a non-contact optical system having a rotation axis located between the first inspection position and the second inspection position, in a plan view defined by the first direction and a second direction intersecting the first direction, the non-contact optical system being configured to inspect a shape of a first inspection surface of a first inspection object at the first inspection position and also configured to inspect a shape of a second inspection surface of a second inspection object, at the second inspection position; and
a first rotator configured to rotate the non-contact optical system about the rotation axis.

2. The flatness inspection apparatus of claim 1, wherein:
the inspection stage includes a plurality of inspection stages;
the plurality of inspection stages comprising:
a first inspection stage including the first inspection position; and
a second inspection stage including the second inspection position.

3. The flatness inspection apparatus of claim 2, further comprising:
a first guide configured to guide movement of the first inspection stage in the second direction and a direction opposite to the second direction;
a second guide configured to guide movement of the second inspection stage in the second direction and the direction opposite to the second direction;
a lifter located between the first guide and the second guide, spaced apart from both the first inspection position and the second inspection position in the second direction, and including a transfer stage configured to move up and down in the first direction in the plan view; and
a second rotator configured to flip over the transfer stage between the first guide and the second guide.

4. The flatness inspection apparatus of claim 3, wherein, in the plan view:
a first virtual line is defined to overlap the first inspection position, the non-contact optical system, and the second inspection position, the first virtual line intersecting the inspection stage;
a second virtual line is parallel to an extension direction of the lifter and intersects the inspection stage, and
a loading position, at which the first inspection object is placed, is located between the first virtual line and the second virtual line, and wherein,
the flatness inspection apparatus is configured to:
move the first inspection object from the loading position to the first inspection position along the first guide, and
move the second inspection object from the loading position to the second inspection position along the second guide via the lifter and the second rotator.

5. The flatness inspection apparatus of claim 2, further comprising:
a first guide configured to guide movement of the first inspection stage in the second direction and a direction opposite to the second direction;
a second guide configured to guide movement of the second inspection stage in the second direction and the direction opposite to the second direction; and
a lifter located between the first guide and the second guide, spaced apart from both the first inspection position and the second inspection position in the second direction, and including a transfer stage configured to move up and down in the first direction in the plan view.

6. The flatness inspection apparatus of claim 5, wherein, in the plan view:
a first loading position overlaps the first inspection position,
a second loading position overlaps the transfer stage when the transfer stage included in the lifter is located at a lowest level; and
the flatness inspection apparatus moves the second inspection object from the second loading position to the second inspection position via the lifter along the second guide.

7. The flatness inspection apparatus of claim 1, wherein,
the inspection stage rotates in conjunction with the non-contact optical system,
when the non-contact optical system does not rotate and is in a first orientation, the flatness inspection apparatus inspects the first inspection object at the first inspection position; and
when the inspection stage and the non-contact optical system rotate from the first orientation to a second orientation, the flatness inspection apparatus inspects the second inspection object at the second inspection position.

8. The flatness inspection apparatus of claim 1, wherein the first and second inspection objects are selected from a group consisting of an electrostatic chuck, a silicon wafer, a mask, and a mask support.

9. The flatness inspection apparatus of claim 8, wherein the silicon wafer is included in a display device including a light-emitting material, or in an electronic device that includes the display device.

10. A flatness inspection apparatus comprising:
a first inspection stage having a first inspection position;
a second inspection stage having a second inspection position, the second inspection position facing the first inspection position in a first direction;
a first non-contact optical system configured to inspect a shape of a first inspection surface of a first inspection object at the first inspection position; and
a second non-contact optical system configured to inspect a shape of a second inspection surface of a second inspection object at the second inspection position.

11. The flatness inspection apparatus of claim 10, further comprising a rotator configured to flip the second inspection stage over.

12. The flatness inspection apparatus of claim 11, wherein, in a plan view defined by the first direction and a second direction intersecting the first direction:
the first loading position overlaps the first inspection position;
the second loading position overlaps the second inspection stage when the second inspection stage is located at a level prior to being flipped over by the rotator; and
the second inspection object is located at the second inspection position by flipping the second inspection stage over by the rotator.

13. The flatness inspection apparatus of claim 10, wherein inspection object is selected from a group consisting of an electrostatic chuck, a silicon wafer, a mask, and a mask support.

14. The flatness inspection apparatus of claim 13, wherein the silicon wafer is included in a display device including a light-emitting material, or in an electronic device that includes the display device.

15. A flatness inspection method comprising:
placing a first inspection object at a first inspection position;
inspecting, in a non-contact manner, a surface shape of a first inspection surface of the first inspection object by a non-contact optical system;
placing a second inspection object at a second inspection position, the second inspection position facing the first inspection position in a first direction;
inspecting, in a non-contact manner, a surface shape of a second inspection surface of the second inspection object by the non-contact optical system; and
determining whether a flatness inspection result meets a predetermined criterion.

16. The flatness inspection method of claim 15,
wherein the step of placing the first inspection object at the first inspection position comprises:
placing the first inspection object on a first inspection stage that includes a loading position; and
locating the first inspection object at the first inspection position by moving the first inspection stage in a second direction intersecting the first direction, and
wherein the step of placing the second inspection object at the second inspection position comprises:
placing the second inspection object on the first inspection stage that includes the loading position;
locating the first inspection stage under a transfer stage by moving the first inspection stage in the second direction;
transferring the second inspection object from the first inspection stage to the transfer stage;
flipping over the transfer stage and moving the transfer stage in the first direction;
transferring the second inspection object from the flipped over transfer stage to the second inspection stage; and
locating the second inspection object at the second inspection position by moving the second inspection stage in an opposite direction to the second direction, and
wherein the step of inspecting the surface shape of the second inspection surface comprises: rotating the non-contact optical system, which has inspected the first inspection position while in a first orientation, towards the second inspection position from the first orientation to a second orientation, and inspecting the second inspection surface.

17. The flatness inspection method of claim 15, wherein a deposition process is performed using the first and second inspection objects when the flatness inspection result meets the predetermined criterion.

18. The flatness inspection method of claim 15, wherein the first and second inspection objects are discarded or subjected to reprocessing if the flatness inspection result does not meet the predetermined criterion.

19. The flatness inspection method of claim 15,
wherein the step of placing the first inspection object at the first inspection position comprises placing the first inspection object on a first inspection stage that includes a first loading position,
wherein the step of placing the second inspection object at the second inspection position comprises:
placing the second inspection object on a transfer stage that includes a second loading position;
moving the transfer stage in the first direction;
transferring the second inspection object from the transfer stage to a second inspection stage; and
locating the second inspection stage at the second inspection position by moving the second inspection stage in an opposite direction to the second direction, and
wherein the step of inspecting the surface shape of the second inspection surface comprises: rotating the non-contact optical system, which has inspected the first inspection position while in a first orientation, towards the second inspection position from the first orientation to a second orientation, and inspecting the second inspection surface.

20. The flatness inspection method of claim 15,
wherein the step of placing the first inspection object at the first inspection position comprises placing the first inspection object on an inspection stage that includes a loading position, and
wherein the step of placing the second inspection object at the second inspection position comprises:
placing the second inspection object on the inspection stage that includes the loading position; and
locating the second inspection object at the second inspection position by rotating in conjunction with the non-contact optical system.
